(19) United States
(12) Patent Application Publication
(10) Pub. No.: US 2011/0141829 A1
(43) Pub. Date: Jun. 16, 2011

(54) Circuits for Reducing Power Consumption of Memory Components

(76) Inventor: Frederick A. Ware, Los Altos Hills, CA (US)

(21) Appl. No.: 12/968,132

(22) Filed: Dec. 14, 2010

Related U.S. Application Data
(60) Provisional application No. 61/286,348, filed on Dec. 14, 2009.

(51) Int. Cl. G11C 5/14; H03K 3/00

(52) U.S. Cl. 365/189.09; 327/295

(57) ABSTRACT

An integrated circuit including one or more data links. A respective data link includes a precharge circuit, a voltage generator circuit, and a transmitter circuit. The precharge circuit is configured to precharge a data line to a predefined voltage level between transmission of symbols on the data line. The voltage generator circuit is configured to generate one or more transmit voltage levels, wherein a respective transmit voltage level represents a respective symbol to be transmitted on the data line and provide current from a voltage source to a transmitter circuit to drive the data line to a transmit voltage level representing a symbol to be transmitted, wherein the current drawn from the voltage source is independent of previously transmitted symbols. The transmitter circuit is configured to receive the symbol to be transmitted and drive the data line to the transmit voltage level using the current provided by the voltage generator circuit.

### RELATED APPLICATIONS

This application claims priority to U.S. Provisional Application Ser. No. 61/286,348, filed Dec. 14, 2009, entitled “Circuits for Reducing Power Consumption of Memory Components,” which is incorporated herein by reference in its entirety.

### TECHNICAL FIELD

The disclosed embodiments relate generally to memory components. In particular, the disclosed embodiments relate to circuits for reducing power consumption of memory components.

### BACKGROUND

Reducing power consumption for electronic devices has several benefits including increasing the battery life for mobile devices. A common technique for reducing power consumption is to reduce the supply voltage. However, reducing the supply voltage also reduces the noise margins. One source of noise is the power source noise produced from currents that are used to charge and discharge transmission lines between memory components. These currents are typically data-dependent. For example, transmitting a 1 followed by a 0 requires current to be sunk to circuit ground whereas transmitting a 0 followed by a 1 requires current to be sourced from a power supply. As the noise margins are reduced, noise that is generated from these currents becomes a larger portion of the noise in the system. Thus, it is highly desirable to provide circuits for reducing power consumption of memory components without the aforementioned problems.

### SUMMARY

Some embodiments provide an integrated circuit including one or more data links. In these embodiments, a respective data link includes a precharge circuit, a voltage generator circuit, and a transmitter circuit. The precharge circuit is configured to precharge a data line to a predefined voltage level between transmission of symbols on the data line. The voltage generator circuit is configured to generate one or more transmit voltage levels, wherein a respective transmit voltage level represents a respective symbol to be transmitted on the data line and provide current from a voltage source to a transmitter circuit to drive the data line to a transmit voltage level representing a symbol to be transmitted, wherein the current drawn from the voltage source is independent of previously transmitted symbols. The transmitter circuit is configured to receive the symbol to be transmitted and drive the data line to the transmit voltage level using the current provided by the voltage generator circuit.

Some embodiments provide an integrated circuit including one or more data links and a voltage generator circuit. In these embodiments, a respective data link includes a transmitter circuit configured to transmit a sequence of symbols onto a respective data line, each symbol being represented by one of a plurality of voltage levels, the respective data link including a precharge circuit configured to precharge the data line to a predefined voltage level between transmission of consecutive symbols in the sequence of symbols, the predefined voltage level being different from any of the plurality of voltage levels used to represent the symbols. The voltage generator circuit is configured to generate one or more of the plurality of voltage levels and provide current from a voltage source to the transmitter circuit, the transmitter circuit being configured to transmit a respective symbol by driving the respective data line to a respective voltage level using the current provided by the voltage generator circuit, wherein the current drawn from the voltage source during transmission of the respective symbol is independent of the sequence of symbols.

In some embodiments, the voltage source supplies a high reference voltage level and a low reference voltage level and the voltage generator circuit includes a first charge-pump voltage supply circuit and a second charge-pump voltage supply circuit. The first charge-pump voltage supply circuit is coupled between the voltage source and the transmitter circuit, and configured to generate a high transmit voltage level that is the sum of the predefined voltage level, and the difference between the high reference voltage level and the low reference voltage level. The second charge-pump voltage supply circuit is coupled between the voltage source and the transmitter circuit, and configured to generate a low transmit voltage level that is the sum of the predefined voltage level, and the difference between the low reference voltage level and the high reference voltage level.

In some embodiments, each of the first and second charge-pump voltage supply circuits includes at least one capacitor, a plurality of switches, and a control circuit configured to selectively close and open the switches to pump charge from the voltage source to the at least one capacitor.

In some embodiments, the first charge-pump voltage supply circuit includes a first switch coupled between a first terminal of a first capacitor and the high reference voltage level, a second switch coupled between a second terminal of the first capacitor and the low reference voltage level, a third switch coupled between the first terminal of the first capacitor and a first terminal of a second capacitor, wherein the voltage level of the first terminal of the second capacitor is substantially at the high voltage level, a fourth switch coupled between the second terminal of the first capacitor and a second terminal of the second capacitor, wherein the voltage level of the second terminal of the second capacitor is the predefined voltage level. The first charge pump also includes a control circuit configured to selectively close and open the first, second, third, and fourth switches, based on predefined conditions, to pump charge from the voltage source to the first capacitor and the second capacitor.

In some embodiments, the second charge-pump voltage supply circuit includes a fifth switch coupled between a first terminal of a third capacitor and the low reference voltage level, a sixth switch coupled between a second terminal of the third capacitor and the high reference voltage level, wherein the voltage level of the first terminal of the third capacitor is substantially at the low voltage level, a seventh switch coupled between the first terminal of the third capacitor and a first terminal of a fourth capacitor, a eighth switch coupled between the second terminal of the third capacitor and a second terminal of the fourth capacitor, wherein the voltage level of the second terminal of the fourth capacitor is the predefined voltage level. The second charge pump also includes a control circuit configured to selectively close and open the fifth, sixth, seventh, and eighth switches, based on predefined conditions, to pump charge from the voltage source to the third capacitor and the fourth capacitor.

In some embodiments, the integrated circuit includes a switched series capacitor voltage generator circuit configured to generate one or more reference voltages including the high reference voltage level and the low reference voltage level.

In some embodiments, the switched series capacitor voltage generator circuit includes one or more capacitors coupled in series to the voltage supply, a transistor coupled to each capacitor, wherein a respective transistor is configured to transfer charge from one terminal of a respective capacitor to another terminal of the respective capacitor in response to a control signal and a control circuit coupled to each capacitor. A respective control circuit is configured to compare node voltages of the respective capacitor to node voltages of a resistor voltage divider and generate the control signal based on the comparison.

In some embodiments, the integrated circuit includes a port for coupling the integrated circuit to the voltage source, wherein the voltage source is external to the integrated circuit.

In some embodiments, the external voltage source is an inductive voltage generator that generates one or more reference voltages including the high reference voltage level and the low reference voltage level.

In some embodiments, the voltage generator circuit includes a first circuit configured to generate a high transmit voltage level that is a voltage level supplied by the voltage source and a second circuit configured to generate a low transmit voltage level that is substantially a ground voltage level.

In some embodiments, the transmitter circuit has an impedance that substantially matches an impedance of the data line.

In some embodiments, the data line is a single ended data line.

In some embodiments, the integrated circuit includes a plurality of the data links, wherein the plurality of data links share a common reference line carrying a reference voltage and each of the data links is configured to be coupled to a single ended data line.

In some embodiments, the integrated circuit includes a switched series capacitor voltage generator circuit configured to generate a plurality of reference voltages including distinct pairs of high and low reference voltage levels for each of the plurality of the data links, wherein each pair of high and low reference voltage levels has a voltage difference that is substantially fixed and substantially the same as the voltage difference as another one of the pairs of high and low reference voltage levels.

In some embodiments, the average of the high and low reference voltage levels of respective pairs of data links is offset by a voltage level that is substantially equal to the voltage difference between the high and low reference voltage levels of a respective data link.

In some embodiments, a first data link and a second data link in the plurality of data links share the same pair of high and low reference voltage levels in the plurality of reference voltage levels.

In some embodiments, a first data link in the plurality of data links uses a first pair of high and low reference voltage levels in the plurality of reference voltage levels and a second data link in the plurality of data links uses a second pair of high and low reference voltage levels in the plurality of reference voltage levels.

In some embodiments, the integrated circuit includes mode control circuitry which, in a first mode, enables the voltage generator circuit, and in a second mode connects a pair of static power supply voltages to the transmitter circuit, wherein the current drawn from the static power supply voltages is dependent on previously transmitted symbols.

In some embodiments, the integrated circuit is selected from the group consisting of a memory controller and a memory device having an array of memory storage cells.

In some embodiments, the one or more data links is selected from the group consisting of external data links and internal data links.

Some embodiments provide a memory module including a substrate and a plurality of the integrated circuits, as described above, mounted on the substrate.

In some embodiments, the each of the plurality of integrated circuits is configured to operate in a first mode, in which current drawn from a voltage source during data transmission is independent on previously transmitted symbols and in a second mode, in which current drawn from a static power supply voltage source during data transmission is dependent on previously transmitted symbols.

In some embodiments, the first mode is a small voltage swing mode and the second mode is large voltage swing mode.

Some embodiments provide a method for transmitting symbols on a data line. A symbol to be transmitted on a data line is received. One or more transmit voltage levels are generated, wherein a respective transmit voltage level represents a respective symbol to be transmitted on the data line. Current is provided from a voltage source to drive the data line to a transmit voltage level representing a symbol to be transmitted, wherein the current drawn from a voltage source is independent of previously transmitted symbols. The data line is then driven to the transmit voltage level using the current and the data line is precharged to a predefined voltage level between transmission of symbols on the data line.

Some embodiments provide a method performed by an integrated circuit device coupled to a voltage source and a plurality of data lines. The integrated circuit transmits a first symbol, including driving a respective data line to a first voltage level by drawing first current from the voltage source, the first voltage level representing the first symbol. After transmitting the first symbol and before transmitting a second symbol, the integrated circuit precharges the respective data line to a predefined voltage level that is different from the first voltage level. The integrated circuit transmits the second symbol that is different in symbol value from the first symbol, including driving the respective data line to a second voltage level by drawing second current from the voltage source, the second voltage level representing the second symbol, the second voltage level being different from the predefined voltage level, the second current being substantially the same as the first current. After transmitting the second symbol and before transmitting a third symbol, the integrated circuit precharges the respective data line to the predefined voltage level. The integrated circuit transmits the third symbol having a same symbol value as the second symbol, including driving the respective data line to a third voltage level by drawing third current from the voltage source, the third voltage level representing the third symbol, the third voltage level being different from the predefined voltage level, the third current being substantially the same as the second current.

### BRIEF DESCRIPTION OF THE DRAWINGS

FIG. 1 is a circuit diagram illustrating a memory controller and a memory device, according to some embodiments.

FIG. 2 is a circuit diagram illustrating a memory controller and a memory device including charge pump circuits that provide current from the power supply that is independent of previously transmitted symbols, according to some embodiments.

FIG. 3 is a circuit diagram illustrating an exemplary charge pump control circuit, according to some embodiments.

FIG. 4A is a circuit diagram illustrating a memory controller and a memory device including charge pump circuits and a reference voltage generator circuit, according to some embodiments.

FIG. 4B illustrates the path of the current from the power supply to ground when the memory device illustrated in FIG. 4A drives a sequence of symbols representing zeros, according to some embodiments.

FIG. 4C illustrates the path of the current from the power supply to ground when the memory device illustrated in FIG. 4A drives a sequence of symbols representing ones, according to some embodiments.

FIG. 5 is a circuit diagram illustrating a portion of a switched series capacitor voltage divider circuit, according to some embodiments.

FIG. 6 is a circuit diagram illustrating a memory controller and a memory device including charge pump circuits, a switched series capacitor voltage divider circuit, and a low-impedance driver in the transceiver of the memory device, according to some embodiments.

FIG. 7 is a circuit diagram illustrating a memory controller and a memory device including charge pump circuits and a switched series capacitor voltage divider circuit, wherein the receiver termination is disabled, according to some embodiments.

FIG. 8A is a circuit diagram illustrating a transceiver circuit of a memory device, wherein the receiver termination is disabled, according to some embodiments.

FIG. 8B is a timing diagram illustrating the transmission of a specified sequence of symbols by transceiver circuit of FIG. 8A, according to some embodiments.

FIG. 9A is a circuit diagram illustrating a memory controller and a memory device including charge pump circuits and a switched series capacitor voltage divider circuit, wherein the data line is precharged to a predetermined voltage level between transmission of symbols, according to some embodiments.

FIG. 9B illustrates the path of the current from the power supply to ground when the memory device illustrated in FIG. 9A drives a sequence of symbols representing zeros, according to some embodiments.

FIG. 9C illustrates the path of the current during a precharge phase between the transmission of each symbol in the sequence of symbols representing zeros, according to some embodiments.

FIG. 9D illustrates the path of the current from the power supply to ground when the memory device illustrated in FIG. 9A drives a sequence of symbols representing ones, according to some embodiments.

FIG. 9E illustrates the path of the current during a precharge phase between the transmission of each symbol in the sequence of symbols representing ones, according to some embodiments.

FIG. 10 is a timing diagram illustrating the transmission of a specified sequence of symbols by a memory device of FIG. 9A, according to some embodiments.

FIG. 11 is a circuit diagram illustrating a memory controller, a memory device including charge pump circuits, and an external voltage generator circuit, according to some embodiments.

FIG. 12 is a circuit diagram illustrating a memory controller, a memory device including charge pump circuits and a low-impedance driver in the transceiver of the memory device, and an external voltage generator circuit, according to some embodiments.

FIG. 13 is a circuit diagram illustrating a memory controller with parallel termination disabled, a memory device including charge pump circuits, and an external voltage generator circuit, according to some embodiments.

FIG. 14 is a circuit diagram illustrating a memory controller with parallel termination disabled, a memory device including charge pump circuits, and an external voltage generator circuit, wherein the data line is precharged to a predetermined voltage level between transmission of symbols, according to some embodiments.

FIG. 15 is a circuit diagram illustrating a memory controller and a memory device including charge pump circuits, wherein the VDD and ground are used as inputs to the charge pumps, according to some embodiments.

FIG. 16 is a circuit diagram illustrating a memory controller and a memory device for the circuit illustrated in FIG. 9A, according to some embodiments.

FIG. 17 is an exemplary timing diagram illustrating the effect of channel length on the transmitted symbols for the circuit illustrated in FIG. 9A, according to some embodiments.

FIG. 18 is another exemplary timing diagram illustrating the effect of channel length on the transmitted symbols for the circuit illustrated in FIG. 9A, according to some embodiments.

FIG. 19 is another exemplary timing diagram illustrating the effect of channel length on the transmitted symbols for the circuit illustrated in FIG. 9A, according to some embodiments.

FIG. 20 is another exemplary timing diagram illustrating the effect of channel length on the transmitted symbols for the circuit illustrated in FIG. 9A, according to some embodiments.

FIG. 21 is a flowchart of a method for transmitting symbols on a data line, according to some embodiments.

FIG. 22 is a flowchart of a method for transmitting symbols on a data line, according to some embodiments.

Like reference numerals refer to corresponding parts throughout the drawings.

### DESCRIPTION OF EMBODIMENTS

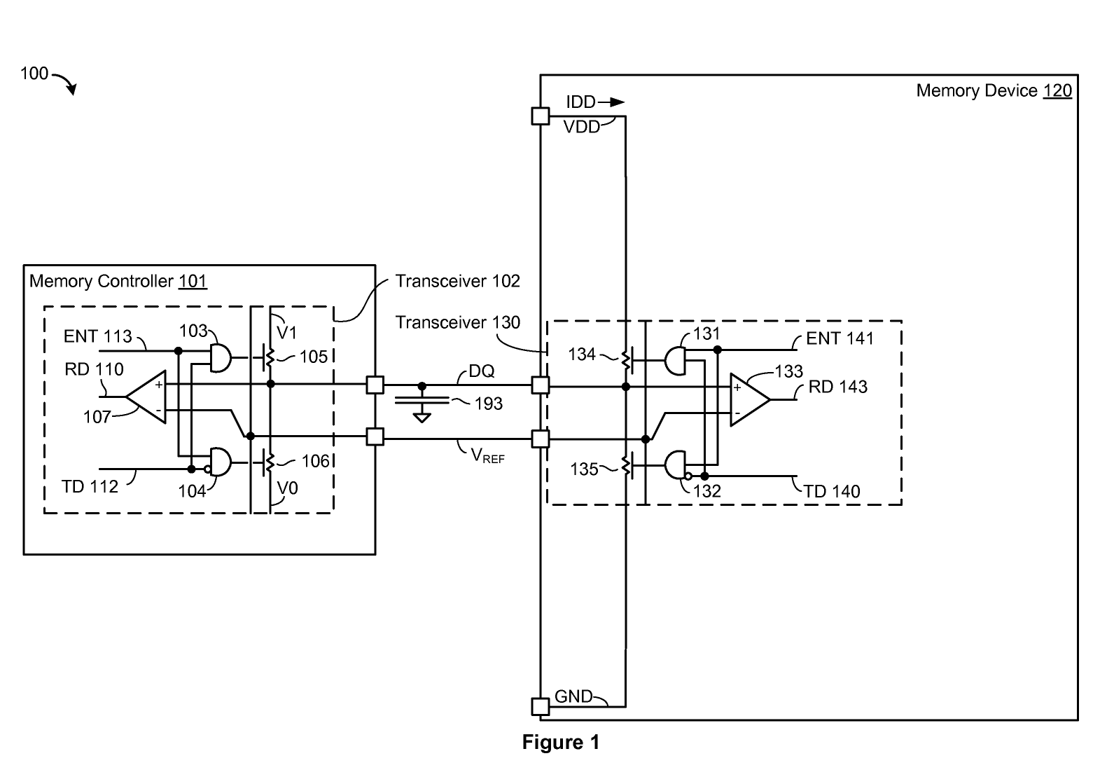

FIG. 1 is a circuit diagram 100 illustrating a memory controller 101 including a transceiver 102 and a memory device 120 including a transceiver 130, according to some embodiments. The memory device 120 is an integrated circuit that includes an array of memory cells accessed by a host device (e.g., the memory controller 101). Note that the memory device 120 may include any suitable type of integrated circuit memory device, such as any type of volatile memory device (e.g., dynamic RAM, static RAM, magnetic RAM, etc.) or any type of non-volatile memory device (e.g., flash memory, read-only memory, EPROM, EEPROM, etc.). The memory controller 101 is also an integrated circuit. The ports of the memory controller 101 and the memory device 120 are coupled to each other via a DQ signal line and a V_{REF} voltage line. The DQ signal line is used for sending signals between the memory controller 101 and the memory device 120. The V_{REF} voltage line is set to a reference voltage level. In some embodiments, the reference voltage level is externally generated. As illustrated, the DQ signal line typically has parasitic capacitance 193. Furthermore, in FIG. 1 (and subsequent figures), the transceivers use singled-ended signaling. In other words, the signal is transmitted via the DQ signal line only.

The transceiver 102 includes pull-up device 105 coupled to a V1 voltage line (e.g., a high voltage level) and pull-down device 106 coupled to a V0 voltage line (e.g., a low voltage level). In some embodiments, the impedance of the pull-up device 105 is substantially equal to the impedance of the DQ signal line. In some embodiments, the impedance of the pull-down device 106 is substantially equal to the impedance of the DQ signal line. The pull-up device 105 is controlled by a logic gate 103 having input signals TD 112 and ENT 113. The pull-down device 106 is controlled by a logic gate 104 having input signals TD 112 and ENT 113. TD 112 is a signal including the data to be transmitted and ENT 113 is a signal including a signal that enables or disables the pull-up device 105 and pull-down device 106. When ENT 113 is high, the pull-up device 105 and the pull-down device 106 are enabled and the transceiver 102 is configured as a transmitter. When ENT 113 is low, the pull-up device 105 and the pull-down device 106 are disabled and the transceiver 102 is configured as a receiver. When the transceiver 102 is configured as a receiver, a differential amplifier 107 compares the voltage on the DQ signal line (i.e., the data signal line) with the reference voltage V_{REF} to produce the signal RD 110 (i.e., the received data signal).

The transceiver 130 is similar to the transceiver 102 and includes pull-up device 134 coupled to a VDD voltage line (i.e., the power supply voltage) and pull-down device 135 coupled to a GND voltage line (i.e., circuit ground). In some embodiments, the impedance of the pull-up device 134 is substantially equal to the impedance of the DQ signal line. In some embodiments, the impedance of the pull-down device 135 is substantially equal to the impedance of the DQ signal line. The pull-up device 134 is controlled by a logic gate 131 having input signals TD 140 and ENT 141. The pull-down device 135 is controlled by a logic gate 132 having input signals TD 140 and ENT 141. TD 140 is a signal including the data to be transmitted and ENT 141 is a signal including a signal that enables or disables the pull-up device 134 and pull-down device 135. When ENT 141 is high, the pull-up device 134 and the pull-down device 135 are enabled and the transceiver 130 is configured as a transmitter. When ENT 141 is low, the pull-up device 134 and the pull-down device 135 are disabled and the transceiver 130 is configured as a receiver. When the transceiver 130 is configured as a receiver, a differential amplifier 133 compares the voltage on the DQ signal line (i.e., the data signal line) with the reference voltage on the V_{REF} voltage line to produce the signal RD 143 (i.e., the received data signal).

For the circuit illustrated in FIG. 1, the current (e.g., I_{DD}) drawn from the power supply (e.g., VDD) is dependent on the symbols being transmitted on the DQ signal line. For example, when the transceiver 130 is transmitting a “1,” the pull-up device 134 draws current from the power supply. When the transceiver 130 is transmitting a “0,” the pull-down device 135 sinks current to ground. For ease of discussion, when the term “ground” is used herein, it shall be understood to mean circuit ground. Thus, the current flowing out of the power supply is dependent on the symbols being transmitted. This data-dependent current flow results in data-dependent currents that cause data-dependent noise (e.g., data-dependent current spikes when transitioning from a 0 to a 1 or a 1 to a 0, etc.). In systems in which the noise margins are reduced (e.g., mobile system, low-voltage swing system, etc.), it is highly desirable to reduce data-dependent noise.

The power consumed by the circuit illustrated in FIG. 1 per symbol transmitted is on the order of

$$\frac{C \cdot {V}_{DD}^{2}}{4 {t}_{bit}} .$$

Assuming that the capacitance C is 8 pF, VDD is 1.2V, and t_{bit} is 1.25 ns, the power consumed per symbol transmitted is on the order of 2.3 mW. t_{bit} is the time period for transmitting a single bit. The inverse of t_{bit} is the frequency at which the bits are transmitted. In systems that transmit two or more bits per symbol period, using four or more voltage levels to represent distinct symbol values, t_{bit} is the time period (i.e., the symbol period) for transmitting a single data symbol and the inverse of t_{bit} is the frequency at which data symbols are transmitted.

Note that the following figures include elements similar to those in FIG. 1. Thus, only the differences in the figures are discussed.

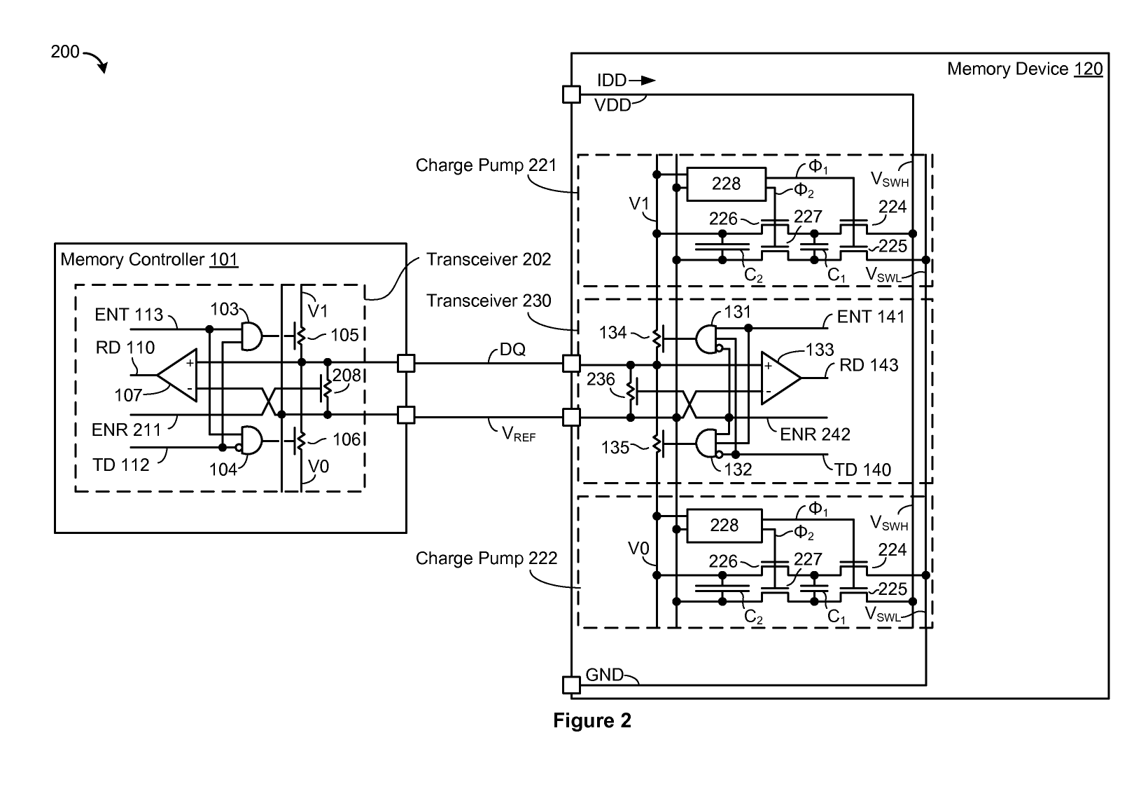

FIG. 2 is a circuit diagram 200 illustrating the memory controller 101 including a transceiver 202 and the memory device 120 including a transceiver 230 and charge pumps 221-222, according to some embodiments. The transceiver 202 is similar to the transceiver 102 except that the transceiver 202 includes a parallel termination device 208. In some embodiments, the parallel termination device 208 can be selectively activated or deactivated using a signal ENR 211. For example, when ENR 211 is high, the parallel termination device 208 is activated and provides parallel termination, and when ENR 211 is low, the parallel termination device 208 is deactivated. The transceiver 230 is similar to the transceiver 130 except that the transceiver 230 includes a parallel termination device 236. In some embodiments, the parallel termination device 236 can be selectively activated or deactivated using a signal ENR 242. For example, when ENR 242 is high, the parallel termination device 236 is activated and provides parallel termination, and when ENR 242 is low, the parallel termination device 236 is deactivated.

Note that for the sake of clarity, the following discussion describes the transceiver 230 being operated as a transmitter and the transceiver 202 being operated as a receiver. However, the transceiver 230 may be operated as a receiver and the transceiver 202 may be operated as a transmitter. Also note that any of the circuitry described herein with respect to the memory device 120 may also be included in the memory controller 101.

The charge pump 221 provides charge to the V1 voltage line, which in turn provides charge to drive the DQ signal line to the high voltage level for transmitting a “1.” The charge pump 221 includes switches 224-227 and a charge pump control circuit 228. A first terminal of the switch 224 is coupled to a high reference voltage level (e.g., VDD). A first terminal of the switch 225 is coupled to a low reference voltage level (e.g., GND). Note that VDD is also referred to as V_{SWH} (the high swing voltage level) and GND is also referred to as V_{SWL} (the low swing voltage level). A second terminal of the switch 224 is coupled to a first terminal of a capacitor C₁ and a first terminal of the switch 226. A second terminal of the switch 225 is coupled to a second terminal of the capacitor C₁ and a first terminal of the switch 227. The second terminal of the switch 226 is coupled to a first terminal of a capacitor C₂ and to the V1 voltage line. The second terminal of the switch 227 is coupled to a second terminal of a capacitor C₂ and to the V_{REF} voltage line.

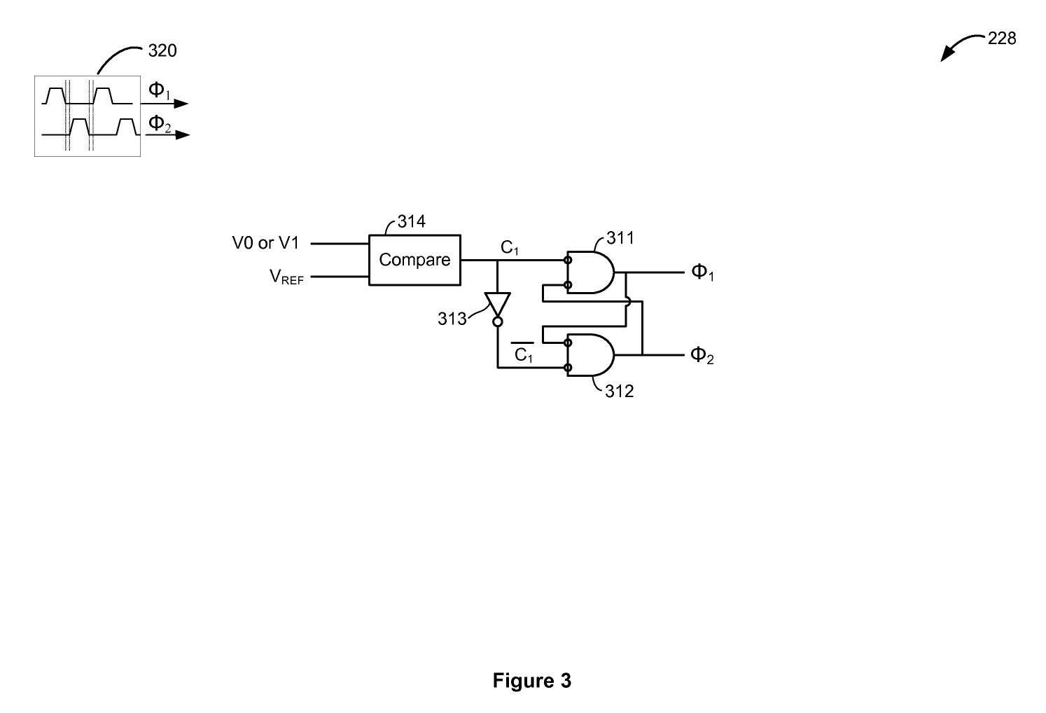

The control terminals of the switches 224 and 225 are coupled to a first control signal Φ₁ generated by a charge pump control circuit 228. The control terminals of the switches 226 and 227 are coupled to a second control signal Φ₂ generated by the charge pump control circuit 228. The control signals Φ₁ and Φ₂ are non-overlapping clocks that open and close the switches 224-227 under specified conditions. Specifically, the charge pump control circuit monitors the voltage on the V1 and V_{REF} voltage lines and generates the control signals Φ₁ and Φ₂ so that the voltage difference between V1 and V_{REF} is maintained at a predetermined voltage. Since the control signals Φ₁ and Φ₂ are non-overlapping, a direct path between the VDD voltage line and V1 is never produced and a direct path between the GND voltage line and V_{REF} is never produced. The generation of the control signals Φ₁ and Φ₂ is described in more detail with respect to FIG. 3. The operation of charge pumps is well known in the art and is not described in this specification. However, it is noted that the capacitors C₁ and C₂ are floating capacitors that allow a voltage difference (or a fraction thereof) referenced to a first reference voltage at the input of the charge pump to be transferred to the output of the charge pump 221 that is referenced to a second reference voltage. For example, the input of the charge pump 221 is referenced to the GND voltage line while the output of the charge pump 221 is referenced to the V_{REF} voltage line. Note that the GND voltage line at the input of the charge pump 221 is in the same path as the V_{REF} voltage line at the output of the charge pump 221. Accordingly, the charge pump 221 transfers the voltage difference (or a fraction thereof) (e.g., VDD) at the input of the charge pump 221 to the output of the charge pump 221 that is referenced to V_{REF} so that V1 is at least a fraction of the voltage difference at the input of the charge pump 221 above V_{REF} (e.g., at least a fraction of VDD above V_{REF}). The actual value of the voltage V1 is controlled by the charge pump control circuit 228.

The charge pump 222 is similar to the charge pump 221 except that the switch 224 is coupled to the GND voltage line and the switch 225 is coupled to the VDD voltage line. This reversal of the voltage inputs transfers the negative difference to the output of the charge pump 222. In this case, the VDD voltage line at the input of the charge pump 222 is in the same path as the V_{REF} voltage line at the output of the charge pump 221. Accordingly, the charge pump 222 transfers the voltage difference (or a fraction thereof) (e.g., −VDD) at the input of the charge pump 222 to the output of the charge pump 222 that is referenced to V_{REF} so that V0 is at least a fraction of the voltage difference at the input of the charge pump 222 below V_{REF} (e.g., at least a fraction of VDD below V_{REF}). The actual value of the voltage V0 is controlled by the charge pump control circuit 228.

The current (e.g., I_{DD}) drawn from the power supply (e.g., VDD) is now independent of the symbols being transmitted on the DQ signal line. When the transceiver 230 is transmitting a “1,” the pull-up driver device 134 draws current from the power supply and when the transceiver 230 is transmitting a “0,” the pull-down driver device 135 pulls current from the power supply. In some embodiments, the pull-up and pull-down drivers 134, 135 and the parallel termination device 236 in the memory device 120 all have substantially the same resistance Rₒ when enabled. Similarly, in some embodiments, the pull-up and pull-down drivers 105, 106 and the parallel termination device 208 in the memory controller 101 all have substantially the same resistance Rₒ when enabled. In some embodiments, the signal ENR 211 is set so that the parallel termination device 208 is enabled and the signal ENR 242 is set so that the parallel termination device 236 is disabled. In these embodiments, the impedance of the pull-up device 134 and the pull-down device 135 are Rₒ.

Although the current drawn from the power supply is no longer data dependent, the power consumed by this embodiment has not improved significantly. The power consumed by the circuit illustrated in FIG. 2 per symbol transmitted is on the order of

$$\frac{{V}_{DD} \cdot ( {V}_{1} - {V}_{REF} )}{2 {R}_{o}} .$$

Assuming that the driver resistance Rₒ is 50 Ohms, VDD is 1.2V, V₁−V_{REF} is 0.2V, and t_{bit} is 1.25 ns, the power consumed per symbol transmitted is on the order of 1.2 mW, which is on the same order as the circuit illustrated in FIG. 1.

FIG. 3 is a circuit diagram illustrating an exemplary charge pump control circuit 228, according to some embodiments. In some embodiments, the charge pump control circuit 228 generates two non-overlapping charge pump signals Φ₁ and Φ₂ based on a signal C₁. As discussed above with reference to FIG. 2, the charge pump signals Φ₁ and Φ₂ are used by charge pumps 221 and 222 to generate V1 and V0, respectively. The charge pump control circuit 228 includes a compare circuit 314, an inverter 313, and cross-coupled NOR gates 311-312. In some embodiments, the compare circuit 314 compares the V0 or the V1 signal to V_{REF} and generates the signal C₁. The compare circuit 314 adjusts the duty cycle of the signal C₁ so that the voltage V0 or V1 is within a predetermined voltage range of V_{REF}. For example, the predetermined voltage range may be V_{REF.}±0.1V. The signal C₁ is fed to one input of the NOR gate 311 and is also fed to an input of the inverter 313 to produce an inverted C₁ signal. The inverted C₁ signal is then fed to the NOR gate 312. The output of the NOR gate 311 is the Φ₁ signal and the output of the NOR gate 312 is the Φ₂ signal. The output of the NOR gate 311 is fed to the other input of the NOR gate 312. Similarly, the output of the NOR gate 312 is fed to the other input of the NOR gate 311. In some embodiments, the signals Φ₁ and Φ₂ are full-swing signals (i.e., rail-to-rail signals).

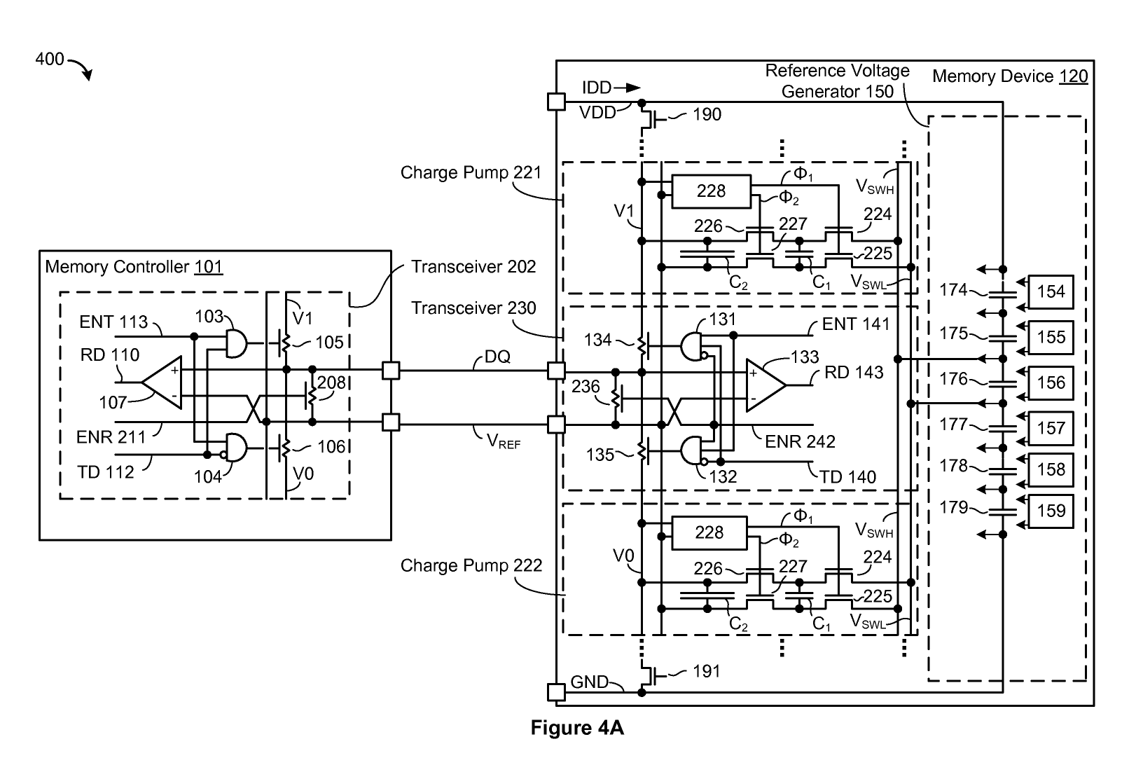

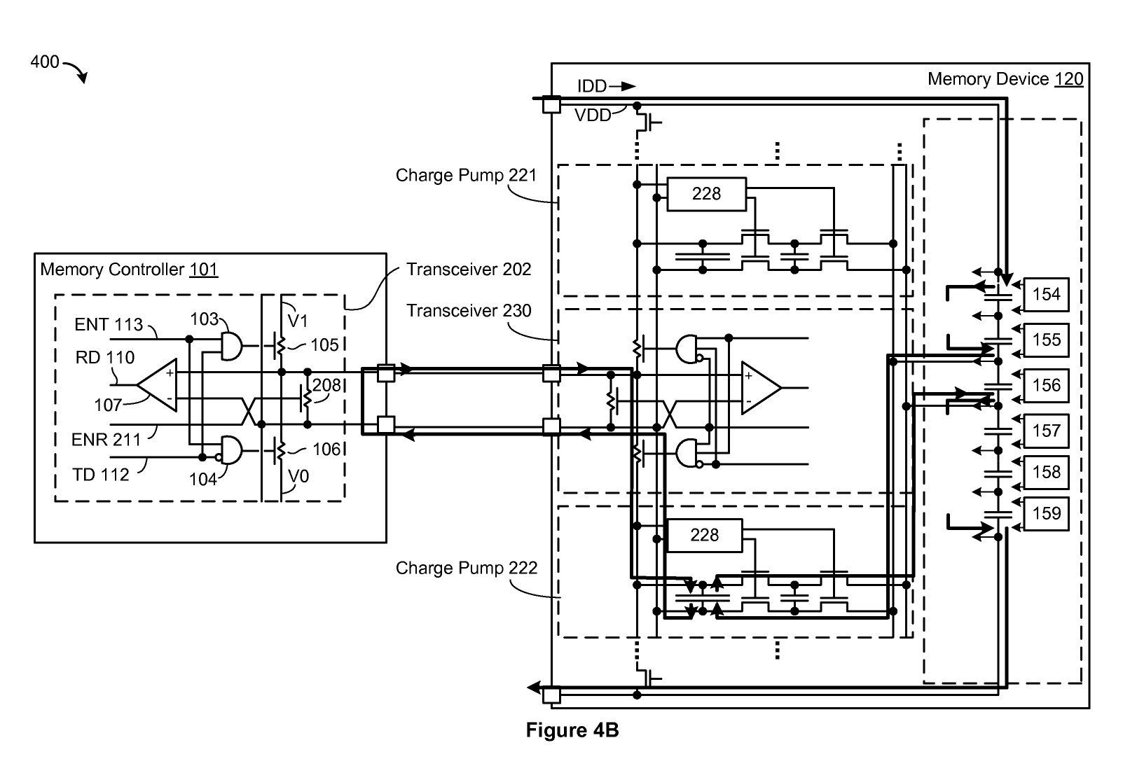

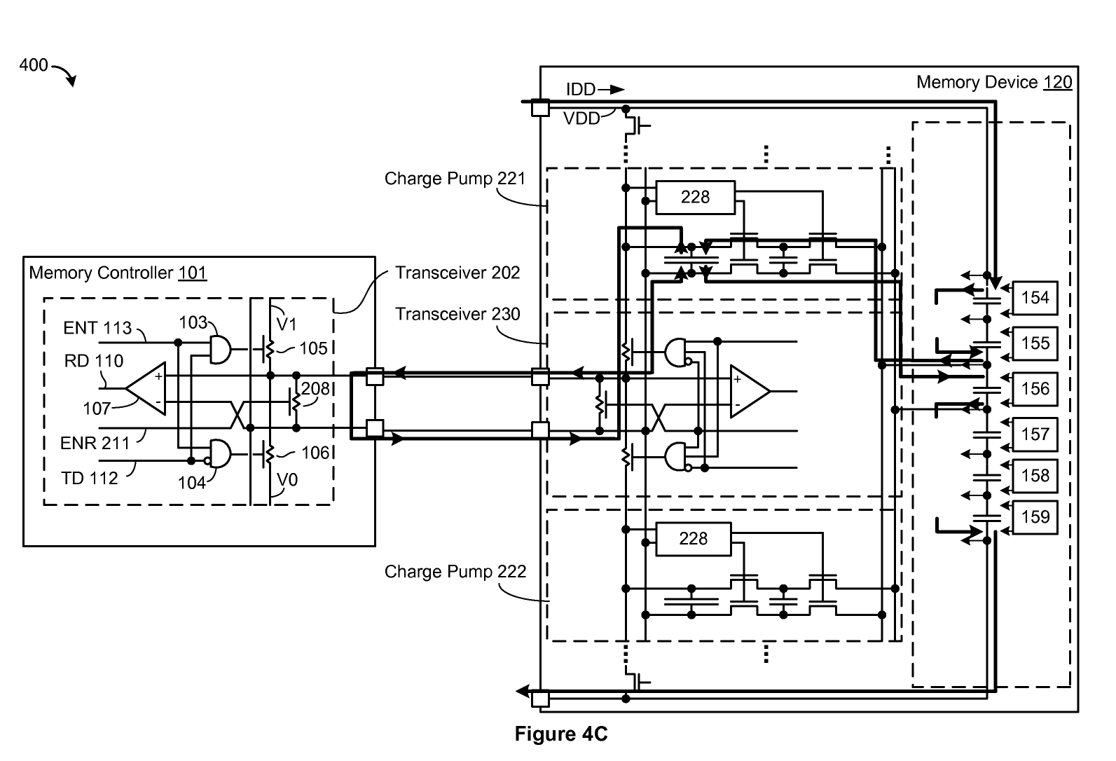

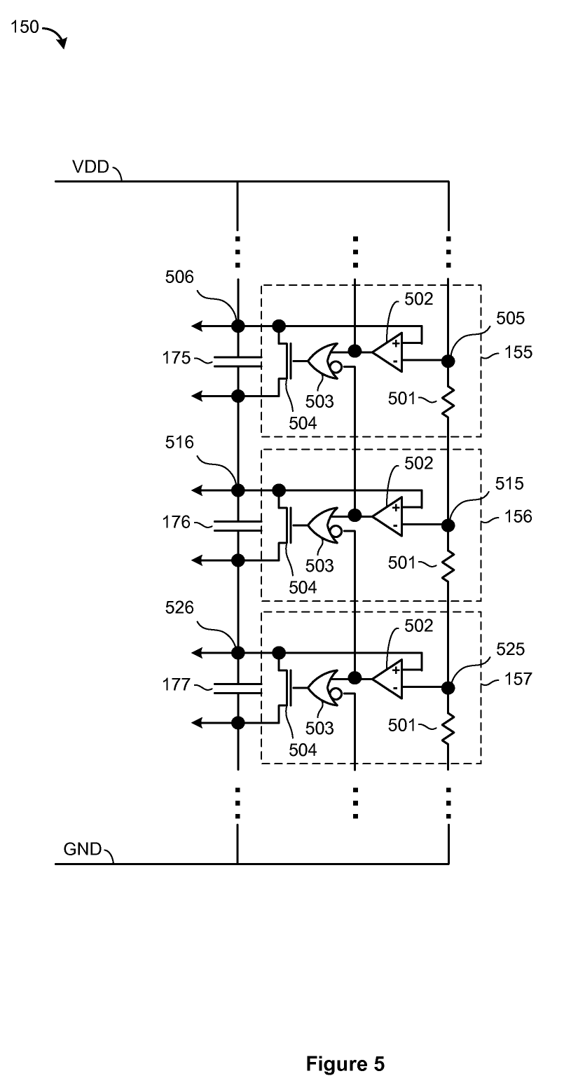

FIG. 4A is a circuit diagram 400 illustrating a memory controller 101 including a transceiver 202 and a memory device 120 including charge pump circuits 221-222 and a reference voltage generator 150, according to some embodiments. The reference voltage generator 150, which can also be called a voltage divider, generates a plurality of voltage levels. In some embodiments, the reference voltage generator 150 is a switched series capacitor voltage generator (e.g., as illustrated in FIG. 4A), which can also be called a switch series capacitor voltage divider. The reference voltage generator 150 includes two or more capacitors (six in this example) 174-179 coupled in series between the VDD voltage line and the GND voltage line. In some embodiments, control circuitry 154-159 ensures that the voltage across each capacitor is substantially fixed and is the same (e.g., within 10% of each other) as the voltage across each of the other capacitors. The voltage across each capacitor is substantially fixed because of circuitry, described below, that automatically adjusts the voltages across the capacitors until the substantially fixed voltages are restored. Attention is now directed to FIG. 5, which is a circuit diagram illustrating a portion of the reference voltage generator 150, according to some embodiments. Each of the control circuit circuits 154-159 include a resistor 501, a differential amplifier 502, an OR gate 503, and a switch 504. The resistors 501 form a resistive voltage divider that determines the difference between the voltages of the terminals of the capacitors. In some embodiments, the resistor 501 in each control circuit 154-159 has substantially the same resistance value (e.g., within manufacturing tolerances). In these embodiments, the voltage across each capacitor is substantially the same.

Referring to the control circuit 156, the amplifier 502 compares the voltage at node 515 with the voltage at node 516. If the voltage at node 516 is greater than the voltage at node 515, the amplifier 502 generates a high voltage signal (e.g., a “1”) that produces a corresponding high voltage signal at the output of the OR gate 503, which closes the switch 504 and allows charge to flow from node 516 to node 526. This flow of charge reduces the voltage at node 516 and increases the voltage at node 526. At the same time, the high voltage signal at the output of the amplifier 502 is inverted at the input of the OR gate 503 in the neighboring control circuit 155. Thus, the OR gate 503 (in control circuit 155) only generates a high voltage signal at its output if the output of the amplifier 502 in the control circuit 155 is a high voltage signal. On the other hand, if the voltage at node 516 is less than the voltage at node 515, the amplifier 502 generates a low voltage signal (e.g., a “0”) that is inverted at the OR gate 503 in the control circuit 155 and produces a corresponding high voltage signal at the output of the OR gate 503 in the control circuit 155, which closes the switch 504 in the control circuit 155 and allows charge to flow from node 506 to node 516. This flow of charge reduces the voltage at node 506 and increases the voltage at node 516. However, the low voltage signal at the output of the amplifier 502 (in control circuit 156) does not, by itself, determine the output of the OR gate 503 in the control circuit 156. Rather, the OR gate 503 (in control circuit 156) generates a high voltage signal at its output if either the output of the amplifier 502 in the control circuit 156 is a high voltage signal or the output of the amplifier in the neighboring control circuit 157 is a low voltage signal. The control circuits 154-159 enable current flows so as to equalize the voltages across the capacitors 174-179. Thus, voltage across each capacitor is substantially fixed and substantially the same (e.g., within 10% of each other).

Returning to FIG. 4A, the voltage at each terminal of a respective capacitor is used as inputs to the charge pumps. As illustrated, the voltage at the top terminal of the capacitor 176 is used as the high reference voltage level and the voltage at the bottom terminal of the capacitor 176 is used as the low reference voltage level for the charge pump 221. The voltage at the top terminal of the capacitor 176 is used as the low reference voltage level and the voltage at the bottom terminal of the capacitor 176 is used as the high reference voltage level for the charge pump 222. In some embodiments, the voltages at the terminals of each of the capacitors are used to provide reference voltage levels to different transceivers in the memory device 120. For example, the voltages of the terminals of the capacitor 175 may be used to provide reference voltage levels to another transceiver in the memory device 120. In some other embodiments, the voltages at the terminals of a single respective capacitor are used to provide reference voltage levels to a plurality of transceivers in the memory device 120. For example, the voltage levels at the terminals of the capacitor 176 may provide reference voltage levels to five sets of transceivers and charge pumps.

In some embodiments, the memory device 120 is configurable to be operated in a legacy mode in which the transmit voltage levels are VDD and GND. In these embodiments, switches 190 and 191 are closed and the charge pumps 221 and 222 are disabled.

As with the circuit illustrated in FIG. 3, the current drawn from the power supply is no longer data dependent. Furthermore, the power consumed by this embodiment has improved by an order of magnitude. The power consumed by the circuit illustrated in FIG. 4A per symbol transmitted is on the order of

$$\frac{{V}_{SW} \cdot ( {V}_{1} - {V}_{REF} )}{2 {R}_{o}} .$$

Assuming that the driver resistance Rₒ is 50 Ohms, VDD is 1.2V, V₁−V_{REF} is 0.2V, V_{SW}=V_{SWH}−V_{SWL}=0.2V, and t_{bit} is 1.25 ns, the power consumed per symbol transmitted is on the order of 0.4 mW, which is about a factor of six less than the power consumed by the circuit illustrated in FIG. 1.

FIG. 4B illustrates the path of the current from the power supply to ground when the memory device 120 illustrated in FIG. 4A drives a sequence of symbols representing zeros, according to some embodiments. Similarly, FIG. 4C illustrates the path of the current from the power supply to ground when the memory device illustrated in FIG. 4A drives a sequence of symbols representing ones, according to some embodiments. As can be seen, regardless of whether the transmitter 230 is transmitting a zero or a one, the current flows in the same direction from the power supply.

In some embodiments, in FIGS. 4A, 4B, and 4C, the signal ENR 211 is set so that the parallel termination device 208 is enabled and the signal ENR 242 is set so that the parallel termination device 236 is disabled. In these embodiments, the impedance of the pull-up device 134 and the pull-down device 135 are Rₒ.

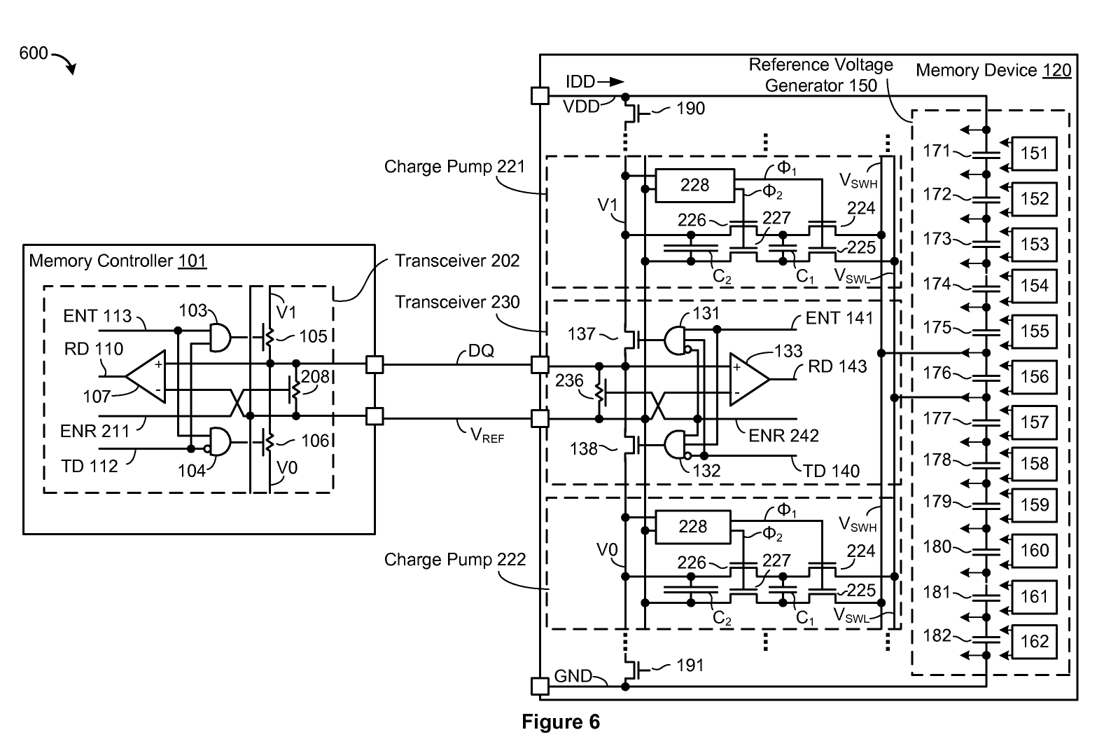

FIG. 6 is a circuit diagram 600 illustrating the memory controller 101 and the memory device 120, according to some embodiments. The circuits in FIGS. 4A and 6 include similar components. Thus, only the differences are discussed. In FIG. 6, the memory device 120 uses low-impedance drivers 137-138 in the transceiver 230. In particular, the low-impedance drivers 137-138 in the transceiver 230 have a resistance (e.g., less than 10 ohms when Rₒ is 50 ohms) that is at least 80% less than the resistance Rₒ of the parallel termination device 236 when enabled. The low impedance devices 137-138 are beneficial for low-swing operation. Thus, the transceiver 230 can transmit signals with a smaller voltage swing than the transceiver 230 in FIG. 4A. In some embodiments, the signal ENR 211 is set so that parallel termination device 208 is enabled and the signal ENR 242 is set so that the parallel termination device 236 is disabled. The memory device 120 in FIG. 6 also includes a reference voltage generator 150 that includes more capacitors 171-182 and control circuits 151-162 than the reference voltage generator 150 in FIG. 4A. Thus, the reference voltage generator 150 in FIG. 6 can supply more discrete reference voltage levels to the transceivers than the reference voltage generator 150 in FIG. 4A. Assuming that the resistance value of the resistor 501 in each control circuit 151-162 in FIG. 6 is the same as the resistance value of the resistor 501 in each control circuit 154-159 in FIG. 4A, the voltage across each capacitor 171-182 in the reference voltage generator 150 in FIG. 6 is smaller than the voltage across each capacitor in the reference voltage generator 150 in FIG. 4A.

Note that when using a high impedance driver, the impedance of the high impedance driver substantially matches the transmission line impedance (e.g., approximately 50 ohms) and the parallel termination device 208 may be disabled. In other words, the transmission line is terminated at the source (i.e., source termination). Thus, signals reflected from the receiver are absorbed by the high impedance driver. Furthermore, when using source termination, no DC power is consumed after the transmission line reaches its final voltage level. Unfortunately, using source termination causes the current required to transmit the signal to be dependent on the data pattern. When using parallel termination (i.e., enabling the parallel termination device 208), the driver impedance may be reduced, as discussed above, and most of the signal power is seen at the receiver instead of being dissipated in the driver. However, DC power is consumed when using parallel termination.

Again, the current drawn from the power supply is no longer data dependent and the power consumed by the circuit illustrated in FIG. 6 per symbol transmitted is on the order of

$$\frac{{V}_{SW} \cdot ( {V}_{1} - {V}_{REF} )}{2 {R}_{o}} .$$

Assuming that the driver resistance Rₒ is 50 Ohms, VDD is 1.2V, V₁−V_{REF} is 0.1V, V_{SW}=V_{SWH}−V_{SWL}=0.1V, and t_{bit} is 1.25 ns, the power consumed per symbol transmitted is on the order of 0.2 mW, which is about half of the power consumed per symbol transmitted using the circuit illustrated in FIG. 4A.

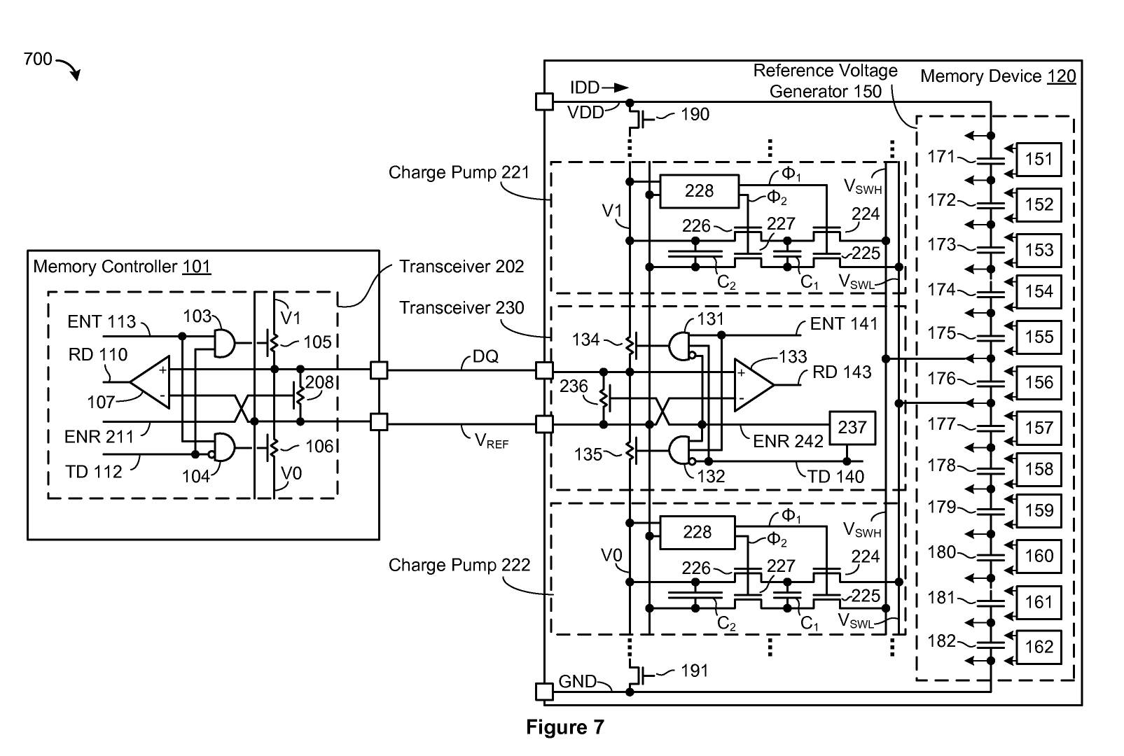

FIG. 7 is a circuit diagram illustrating the memory controller 101 and the memory device 120, according to some embodiments. The circuits in FIGS. 6 and 7 include similar components. Thus, only the differences are discussed. In these embodiments, the signal ENR 211 is set so that the parallel termination device 208 is disabled and the signal ENR 242 is set by the control circuit 237 so that the parallel termination device 236 is in a synchronization mode, also called the “SYN” mode. When the parallel termination device 236 is in the SYN mode, control circuit 237 compares a current symbol to a previously transmitted symbol and generates the signal ENR 242 so that the parallel termination device 236 is enabled for a predefined length of time (e.g., t_{BIT}/4) at the beginning a symbol period only when the current symbol is the same as the previously transmitted. In these embodiments, the impedance of the pull-up device 134 and the pull-down device 135 are Rₒ. For example, if the current symbol and the previously transmitted symbol are the same (e.g., both 1s or both 0s), the control circuit 237 sets the signal ENR 242 so that the parallel termination device 236 is turned on prior to transmitting the current symbol. In doing so, a current flows from the power supply through the parallel termination device 236. This current emulates the current that would flow from the power supply if a 0 and then a 1 (or a 1 and then a 0) were transmitted and ensures that the current flowing from the power supply is independent of the symbols transmitted. To clarify, when transmitting a sequence of the same symbols (e.g., 1s or 0s), substantially no current is drawn from the power supply because the DQ signal line is already at the desired voltage level. Thus, the current drawn from the power supply is data dependent. To remove the data-dependency of the current drawn from the power supply, the control circuit 237 (when operating in the synchronization mode) activates the parallel termination device 236 to draw current from the power supply when transmitting a sequence of the same symbol.

Again, the current drawn from the power supply is no longer data dependent and the power consumed by the circuit illustrated in FIG. 7 per symbol transmitted is on the order of

$$\frac{C \cdot {( {V}_{1} - {V}_{0} )}^{2}}{2 {t}_{BIT}} .$$

Assuming that C is 8 pF, V₁−V₀ is 0.2V, and t_{bit} is 1.25 ns, the power consumed per symbol transmitted is on the order of 0.13 mW, which is less than but on the same order as the power consumed by symbol transmitted by the circuits illustrated in FIGS. 4A and 6.

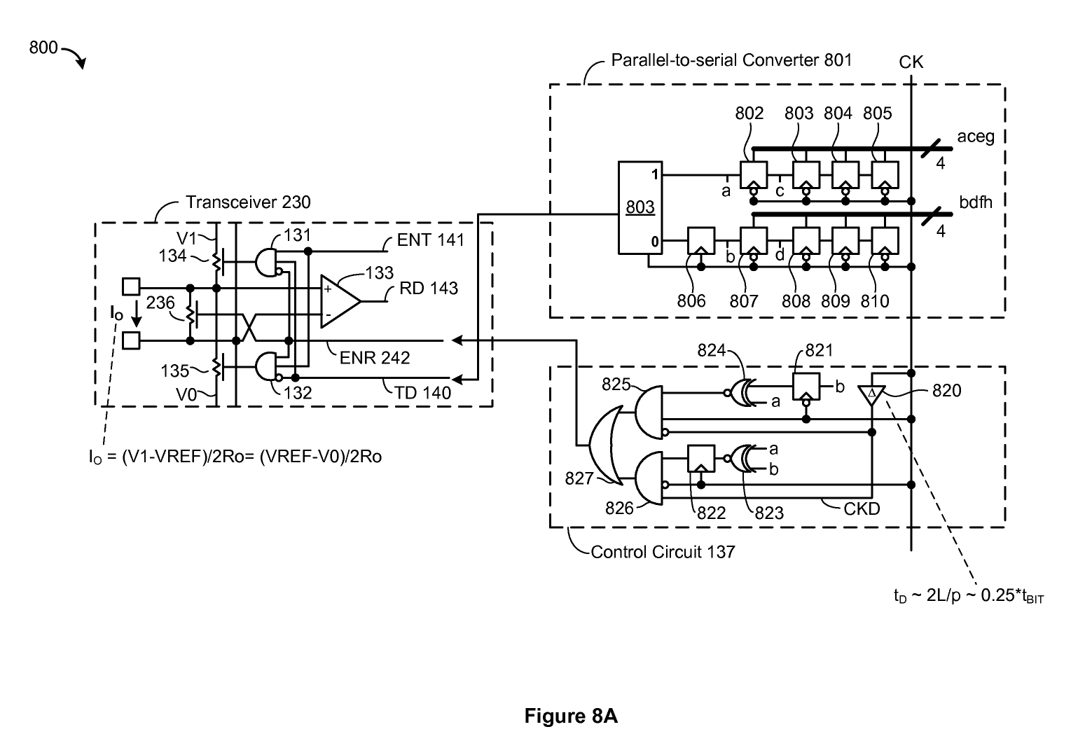

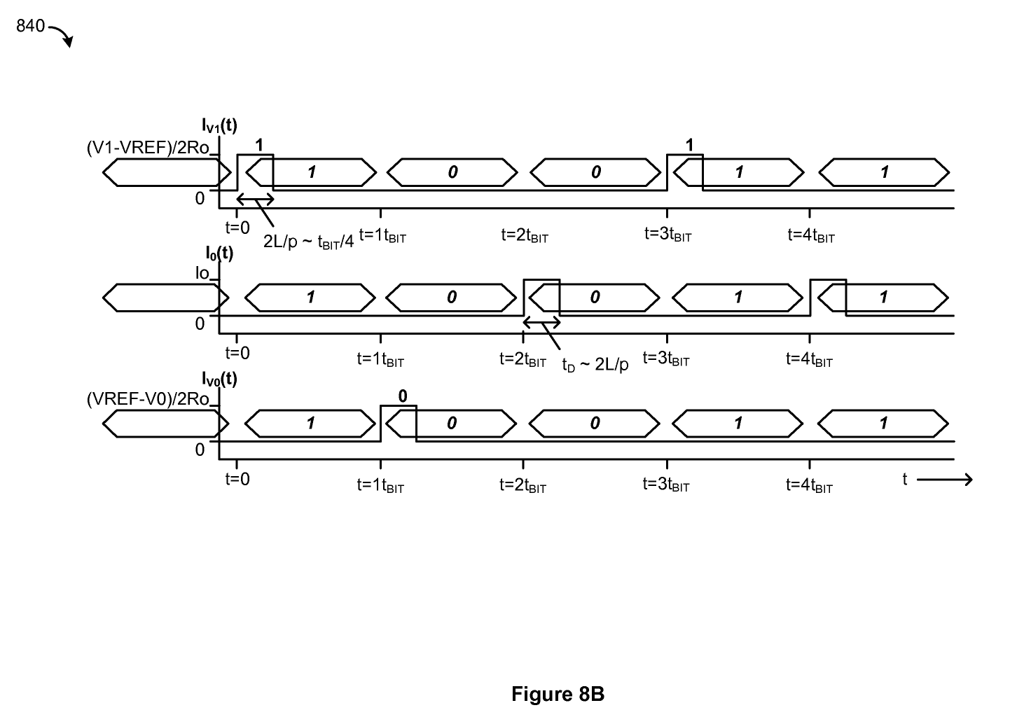

FIG. 8A is a circuit diagram 800 illustrating the transceiver circuit 230 of the memory device 120 illustrated in FIG. 7, a parallel-to-serial converter 801, and the control circuit 237, according to some embodiments. The parallel-to-serial converter 801 includes a series of registers 802-805 and a series of registers 806-810. The symbols to be transmitted are sequentially distributed between the registers 802-805 and 806-807. For example, if the symbols to be transmitted are abcdefgh (in that order), the symbols aceg are sent to the registers 802-805 and the symbols bdfh are sent to the registers 806-810. The registers 802-810 are clocked by a clock signal CK. Note that the clock inputs of the registers 802-805 and 807-810 are inverted while the clock input of the register 806 is not inverted. Thus, the symbol in the register 802 is available to a multiplexer 803 within a specified time interval after CK goes low (e.g., after the value of the register settles) while the symbol in the register 806 is available to the multiplexer 803 within a specified time interval after CK goes high (e.g., after the value of the register settles). The multiplexer 803 is controlled by a clock signal CK. When CK is high, the multiplexer selects the “1” input (i.e., the output of the register 802). When CK is low, the multiplexer selects the “0” input (i.e., the output of the register 806). Thus, the output of register 802 is transmitted in the high clock phase and the output of the register 806 is transmitted in the low clock phase.

The control circuit 237 includes delay element 820, registers 821 and 822, and logic gates 823-827. These elements are configured so that when a previously transmitted symbol and a current symbol have the same value, the signal ENR 242 is set to enable the parallel termination device 236 for a specified time period (e.g., t_{BIT}/4). Otherwise, these elements are configured to set the signal ENR 242 to disable the parallel termination device 236. As noted above, this mode of operation of the control circuit 237 and parallel termination device 236 is sometimes called the synchronization mode, or “SYN” mode. In these embodiments, the impedance of the pull-up device 134 and the pull-down device 135 are Rₒ.

FIG. 8B is a timing diagram 840 illustrating the transmission of a specified sequence of symbols by transceiver circuit of FIG. 8A, according to some embodiments. In this timing diagram, the sequence of symbols is 1011. As illustrated in FIG. 8B, the current flowing through the V1 voltage line, I_{V1}(t), has a value of (V1−VREF)/2Rₒ for a specified time period (e.g., t_{BIT}/4) after the DQ signal line transitions from a 0 to a 1. Similarly, the current flowing through the V0 voltage line, I_{V0}(t), has a value of (VREF−V0)/2Rₒ for a specified time period (e.g., t_{BIT}/4) after the DQ signal line transitions from a 1 to a 0. Furthermore, the current flowing through the resistor Rₒ, I_{Ro}(t), has a value of (V1−VREF)/2Rₒ (or (VREF−V0)/2Rₒ) for a specified time period (e.g., t_{BIT}/4) in between the transmission of the same symbol.

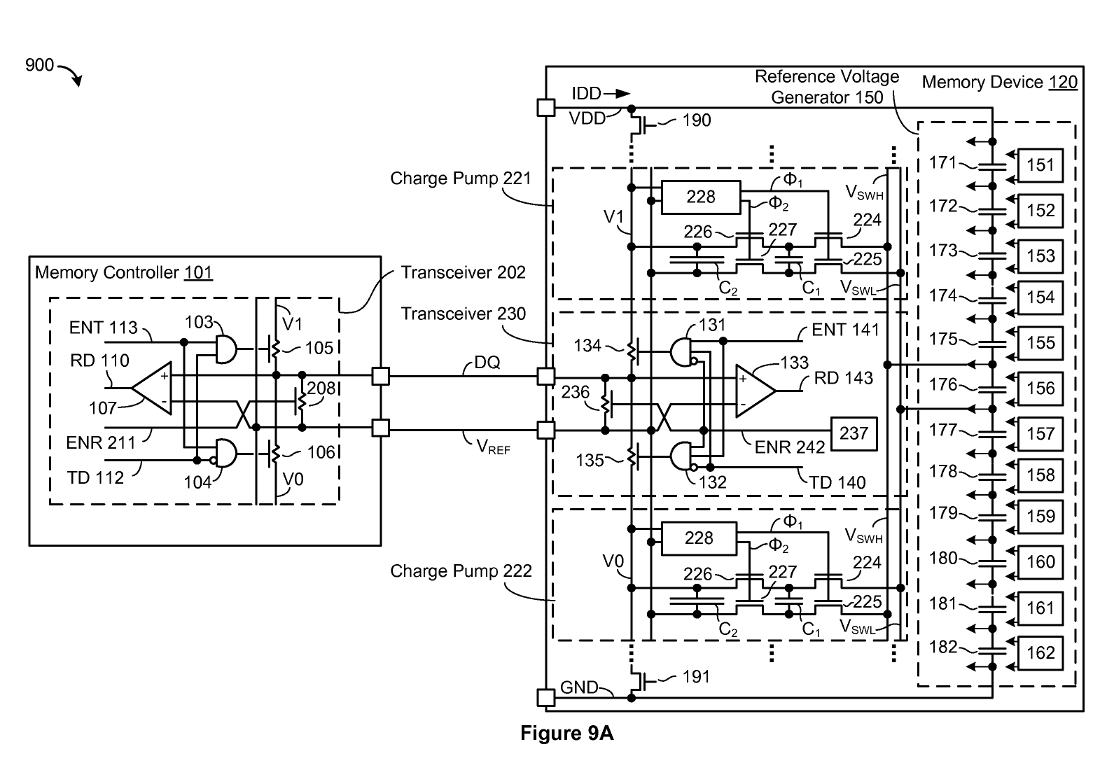

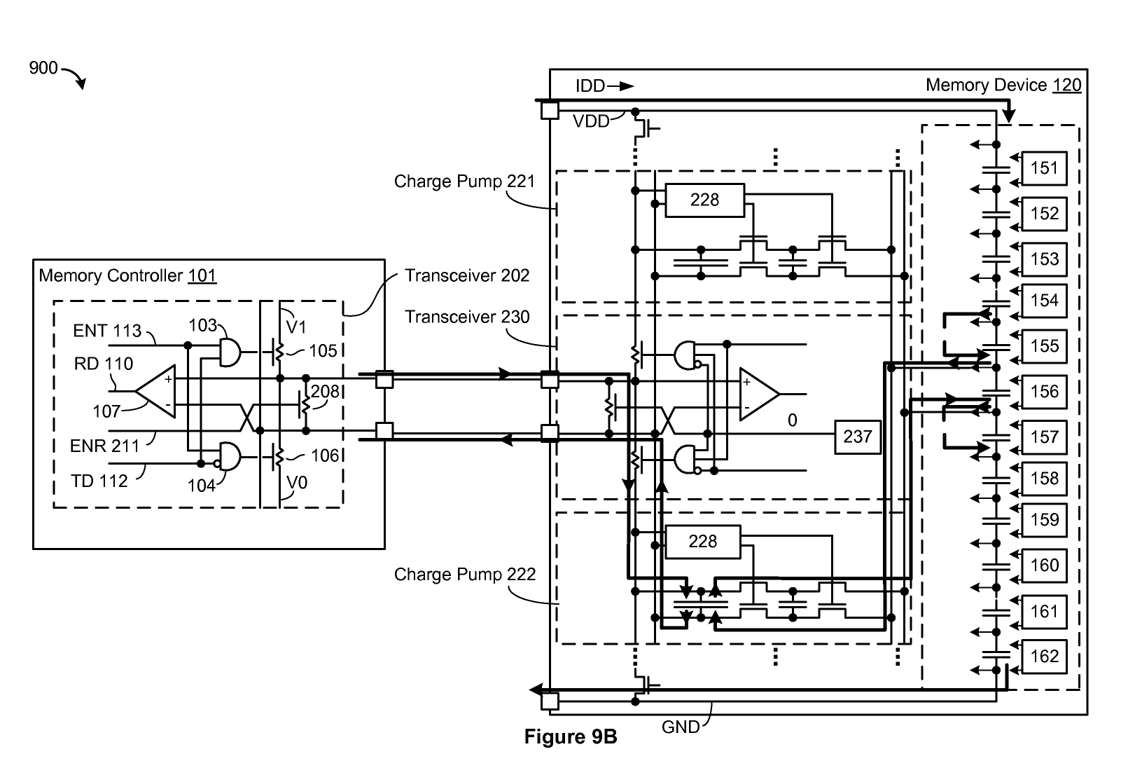

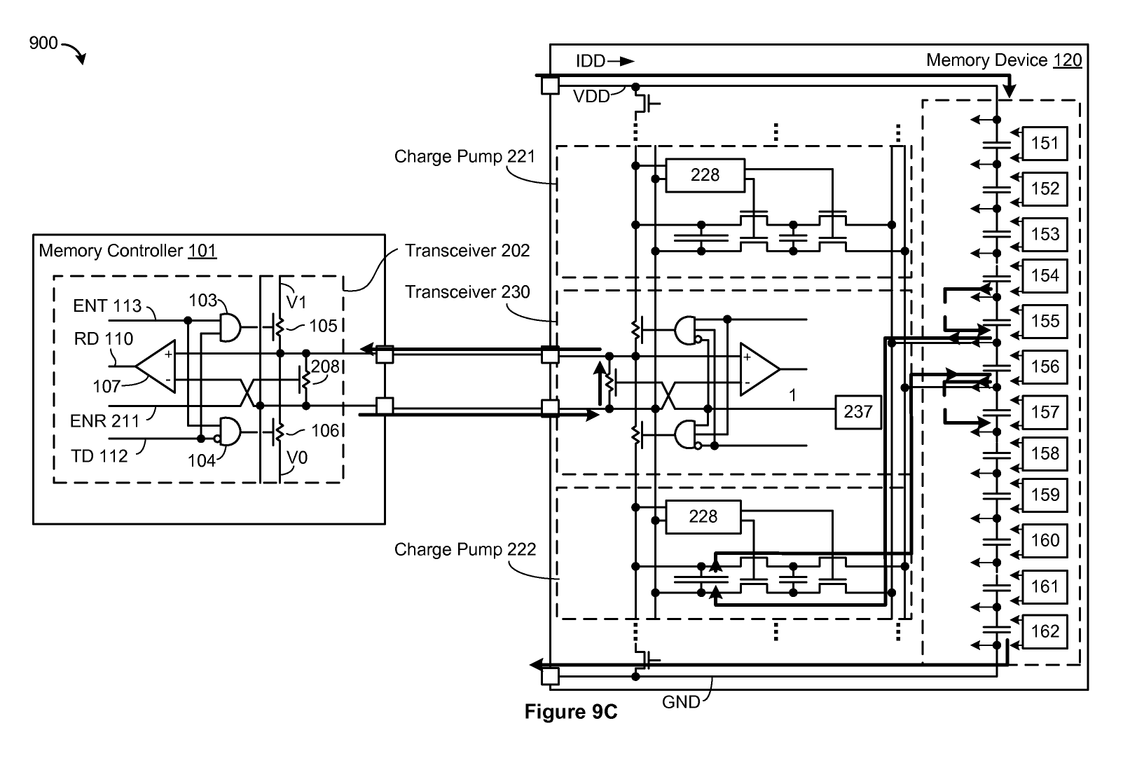

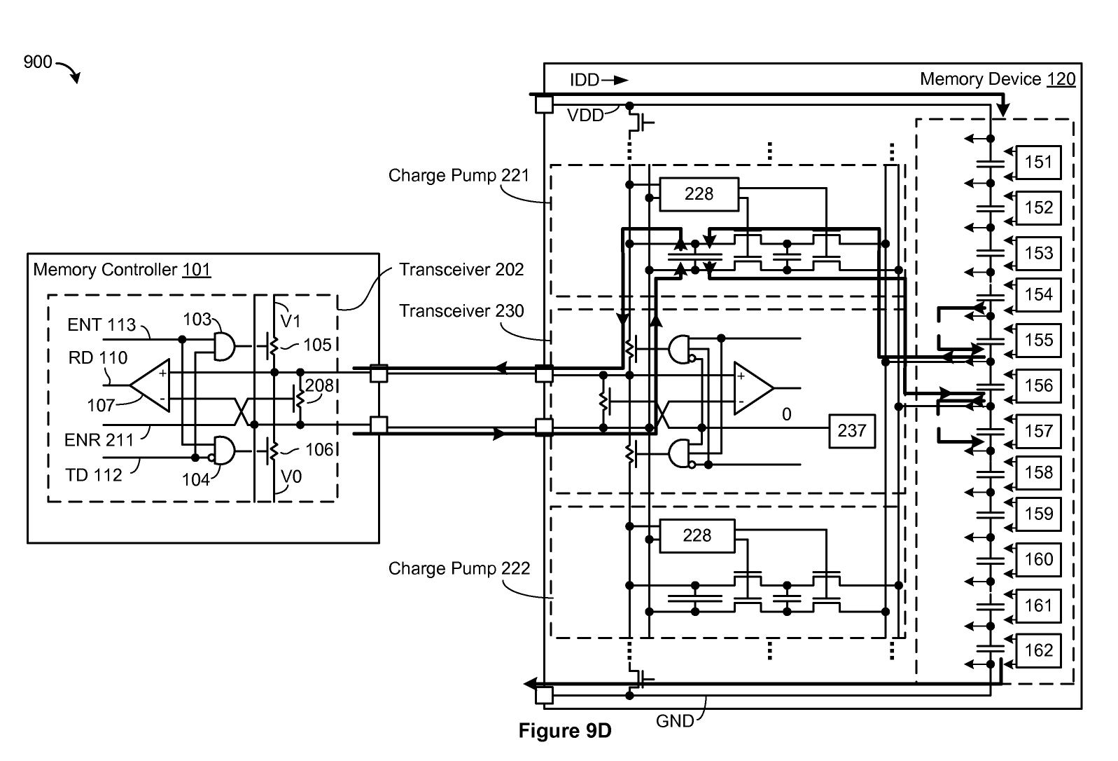

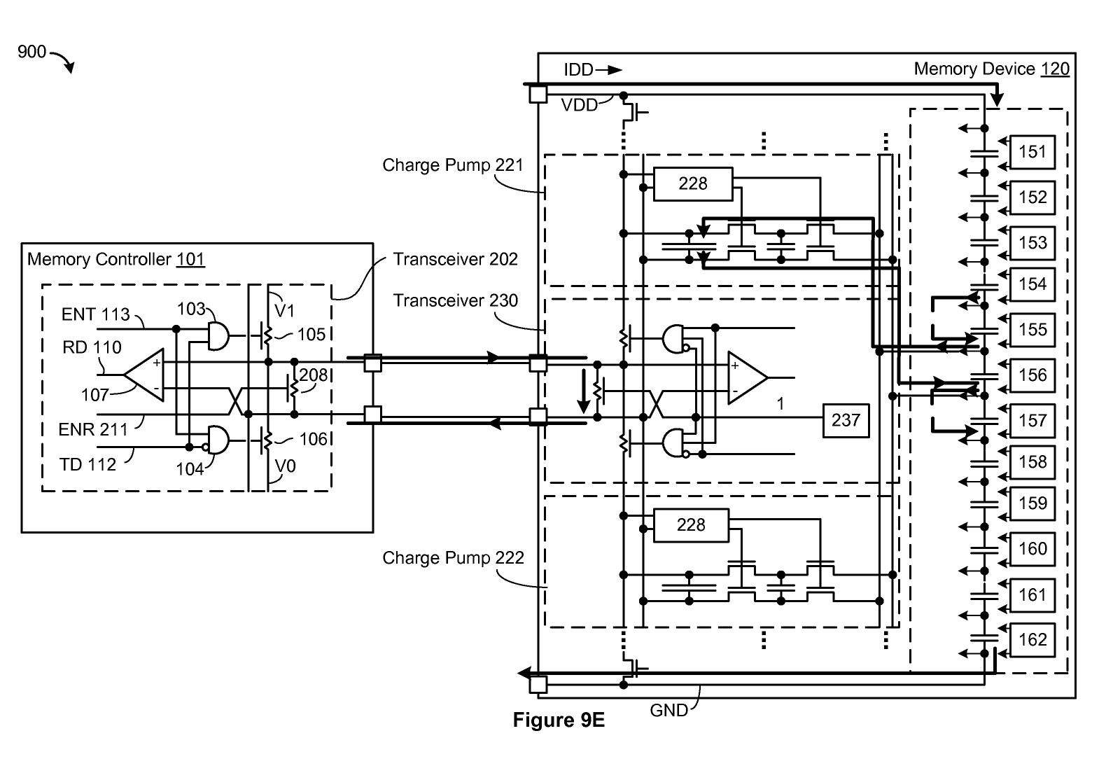

FIG. 9A is a circuit diagram 900 illustrating the memory controller 101 and the memory device 120, according to some embodiments. The circuits in FIGS. 7 and 9A include similar components. Thus, only the differences are discussed. In embodiments represented by FIG. 9A, the data line DQ is precharged to a predetermined voltage level (e.g., VREF) between the transmission of symbols. Specifically, the control circuit 237 sets the signal ENR 242 to activate the parallel termination device 236 between the transmission of symbols and sets the signal ENR 242 to disable the parallel termination device 236 during the transmission of symbols. In addition, the pull-up device 134 and the pull-down device 135 are disabled during the precharge phase.

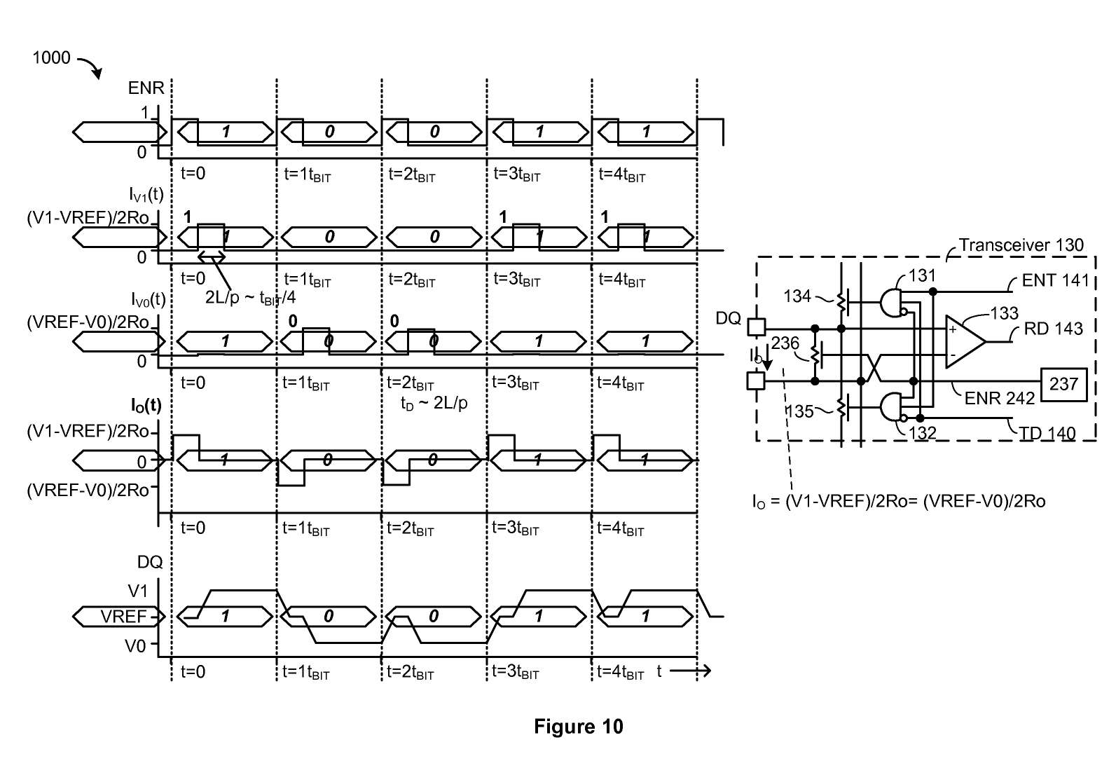

Precharging the DQ signal line between the transmission of symbols ensures that the current drawn from the power supply is substantially the same for all symbols transmitted even for a sequence of symbols that have the same value, as discussed above with respect to FIG. 7 above. Furthermore, by precharging the DQ signal line, the maximum voltage transition is reduced. Specifically, the DQ signal line only transitions from VREF to V1 or VREF to V0. Thus, the power supply only needs to supply current for this reduced voltage swing. FIG. 10 is a timing diagram 1000 illustrating the transmission of a specified sequence of symbols by the memory device 120 illustrated in FIG. 9A, according to some embodiments. Specifically, the sequence of symbols is 10011. As illustrated in FIG. 10, the signal ENR 242 is enabled only between the transmission of each symbol. Also note that the voltage on the DQ signal line always returns to VREF in between the transmission of each data symbol.

Returning to FIG. 9A, the current drawn from the power supply is no longer data dependent and the power consumed by the circuit illustrated in FIG. 9A per symbol transmitted is on the order of

$$\frac{C \cdot {( {V}_{1} - {V}_{REF} )}^{2}}{{t}_{BIT}} .$$

Assuming that C is 8 pF, V₁−V₀ is 0.1V, and t_{bit} is 1.25 ns, the power consumed per symbol transmitted is on the order of 0.06 mW, which is a factor of two improvement over the circuit illustrated in FIG. 7.

FIG. 9B illustrates the path of the current from the power supply to ground when the memory device illustrated in FIG. 9A drives a sequence of symbols representing zeros, according to some embodiments. The current flows from the power supply through each data link (e.g., transceiver), to the low reference voltage input of the charge pump 222, to the VREF voltage line. A current flows from the DQ signal line back out of the high reference voltage input of the charge pump 222 and eventually to GND. As illustrated in FIG. 9C, a current flows from the VREF voltage line through the parallel termination device 236 to charge the DQ data line during a precharge phase. This is the same current that flowed from the power supply to the VREF voltage line during the transmission of the zero.

FIGS. 9D and 9E illustrate the analogous process for driving a sequence of symbols representing ones.

In some embodiments, for FIGS. 9A to 9E, the signal ENR 211 is set so that the parallel termination device 208 is disabled and the control circuit 237 sets the signal ENR 242 to be enabled between symbol transmissions so that the parallel termination device 236 operates in a precharge mode, sometimes called the “PRE” mode. In the precharge mode, the signal ENR 242 is disabled during signal transmissions. When the control circuit 237 and parallel termination device 236 operate in the precharge mode, the DQ signal line is precharged between the transmission of symbols by current flowing through the parallel termination device 236. In these embodiments, the impedance of the pull-up device 134 and the pull-down device 135 are Rₒ.

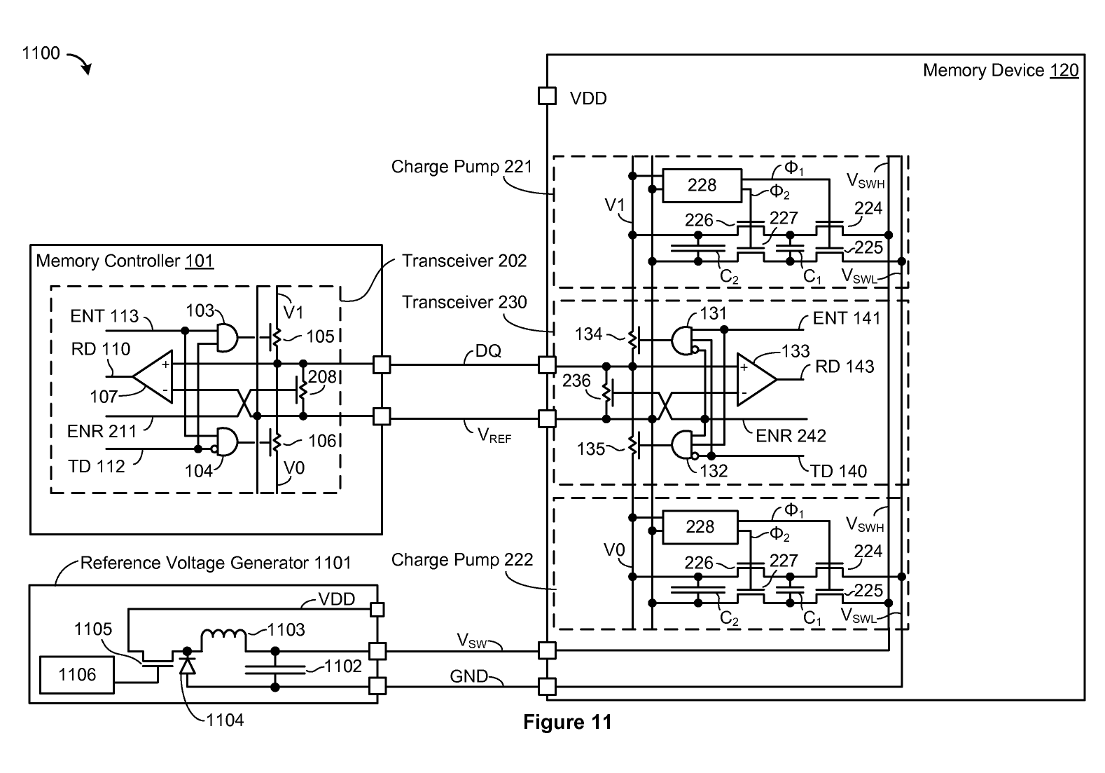

FIG. 11 is a circuit diagram 1100 illustrating the memory controller 101, the memory device 120, according to some embodiments. In these embodiments, instead of generating the reference voltage levels on the memory device 120, the reference voltage levels are generated using an external voltage generator 1101. In some embodiments, reference voltage generator 1101 is a Buck Converter (i.e., an inductive voltage generator). In these embodiments, the reference voltage generator 1101 includes a capacitor 1102, an inductor 1103, a diode 1104, a switch 1105, and a control circuit 1106. The control circuit 1106 adjusts the duty cycle of the switch 1105 (which conveys input voltage VDD to a terminal of the indictor 1103 when the switch is closed), which in turn determines the value of the voltage V_{SW}. For example, if the duty cycle is set to ⅙ (approximately 16%) and VDD is 1.2V, V_{SW} is approximately 0.2V. The power consumed by the circuit illustrated in FIG. 11 per symbol transmitted is on the order of

$$\frac{{V}_{SW} \cdot ( {V}_{1} - {V}_{REF} )}{2 {R}_{o}} .$$

Assuming that Rₒ is 50 ohms, VDD is 1.2V, V₁−V_{REF} is 0.2V, V_{SW} is 0.2V, and t_{bit} is 1.25 ns, the power consumed per symbol transmitted is on the order of 0.4 mW.

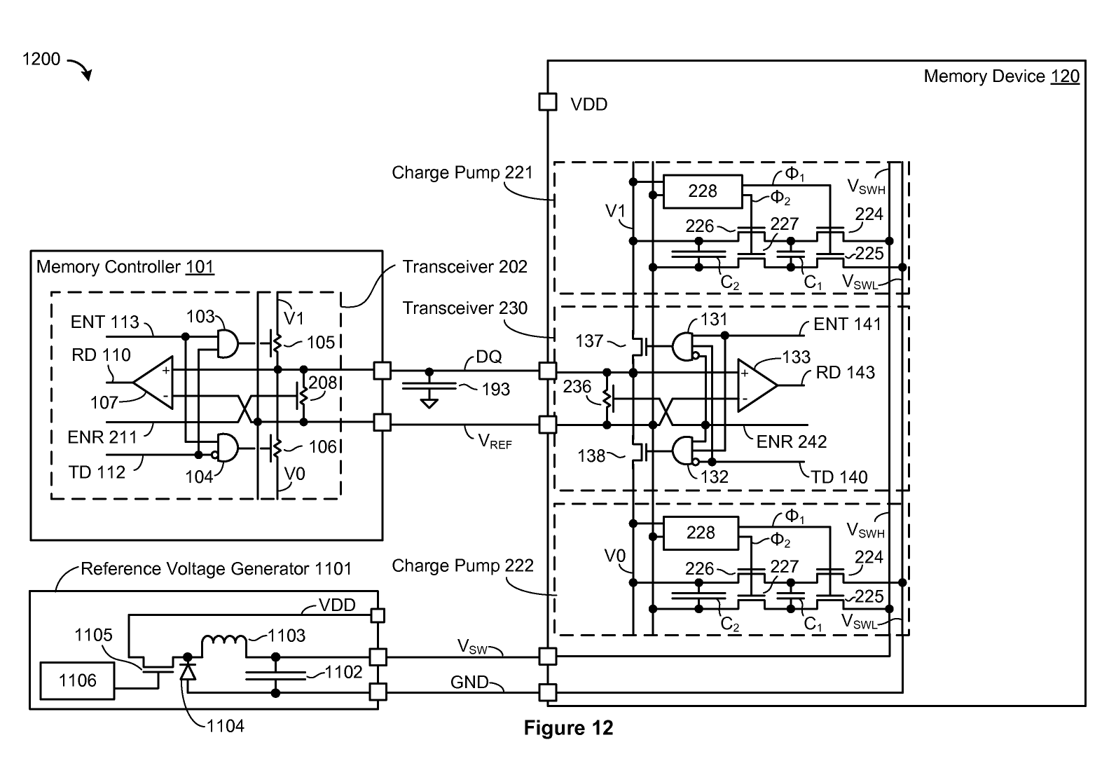

FIG. 12 is a circuit diagram 1200 illustrating an alternative embodiment of the circuit illustrated in FIG. 11, according to some embodiments. Specifically, the transceiver 230 uses low-impedance drivers 137-138 to improve the power consumption for low-swing operation. The power consumed by the circuit illustrated in FIG. 12 per symbol transmitted is on the order of

$$\frac{{V}_{SW} \cdot ( {V}_{1} - {V}_{REF} )}{ {R}_{o}} .$$

Assuming that Rₒ is 50 ohms, VDD is 1.2V, V₁−V_{REF} is 0.1V, V_{SW} is 0.1V, and t_{bit} is 1.25 ns, the power consumed per symbol transmitted is on the order of 0.2 mW.

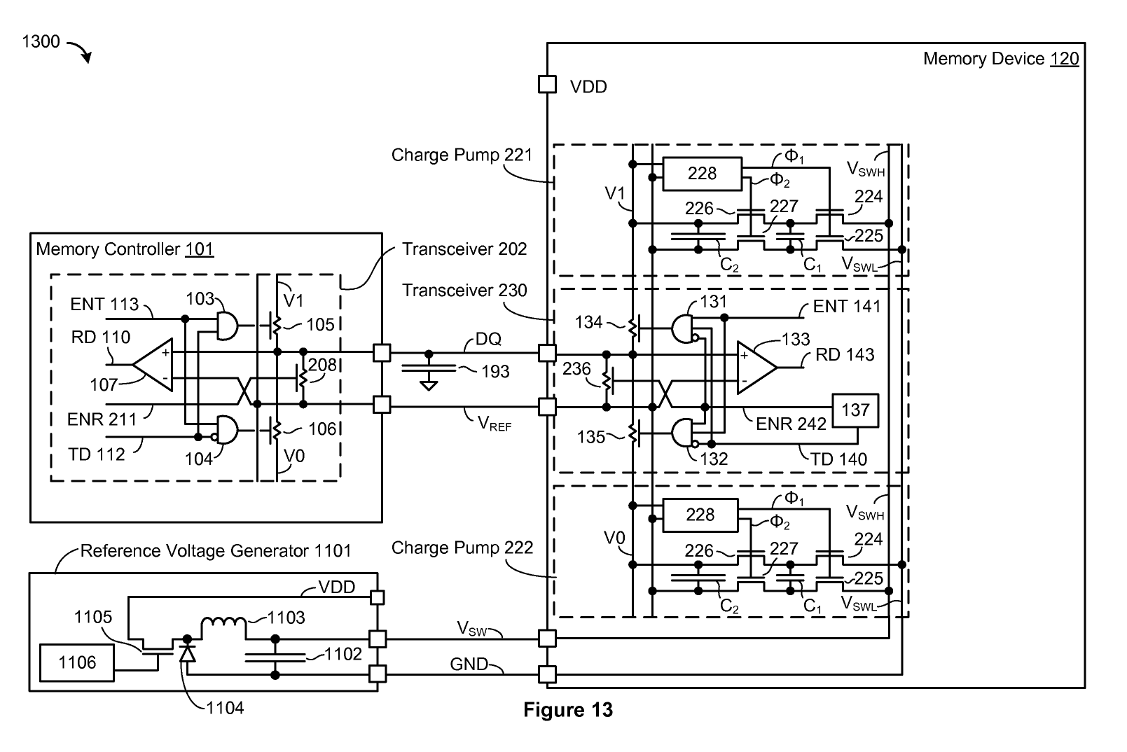

FIG. 13 is a circuit diagram 1300 illustrating an alternative embodiment of the circuit illustrated in FIG. 11, according to some embodiments. Specifically, the parallel termination device 208 in the memory controller 101 is disabled. Furthermore, the control circuit 237 compares a current symbol to a previously transmitted signal and generates the signal ENR 242 to enable or disable the parallel termination device 236 in the transceiver 230, as described with respect to FIG. 7. The power consumed by the circuit illustrated in FIG. 13 per symbol transmitted is on the order of

$$\frac{C \cdot {( {V}_{1} - {V}_{0} )}^{2}}{2 {t}_{BIT}} .$$

Assuming that C is 8 pF V₁−V₀ is 0.2V, and t_{bit} is 1.25 ns, the power consumed per symbol transmitted is on the order of 0.13 mW.

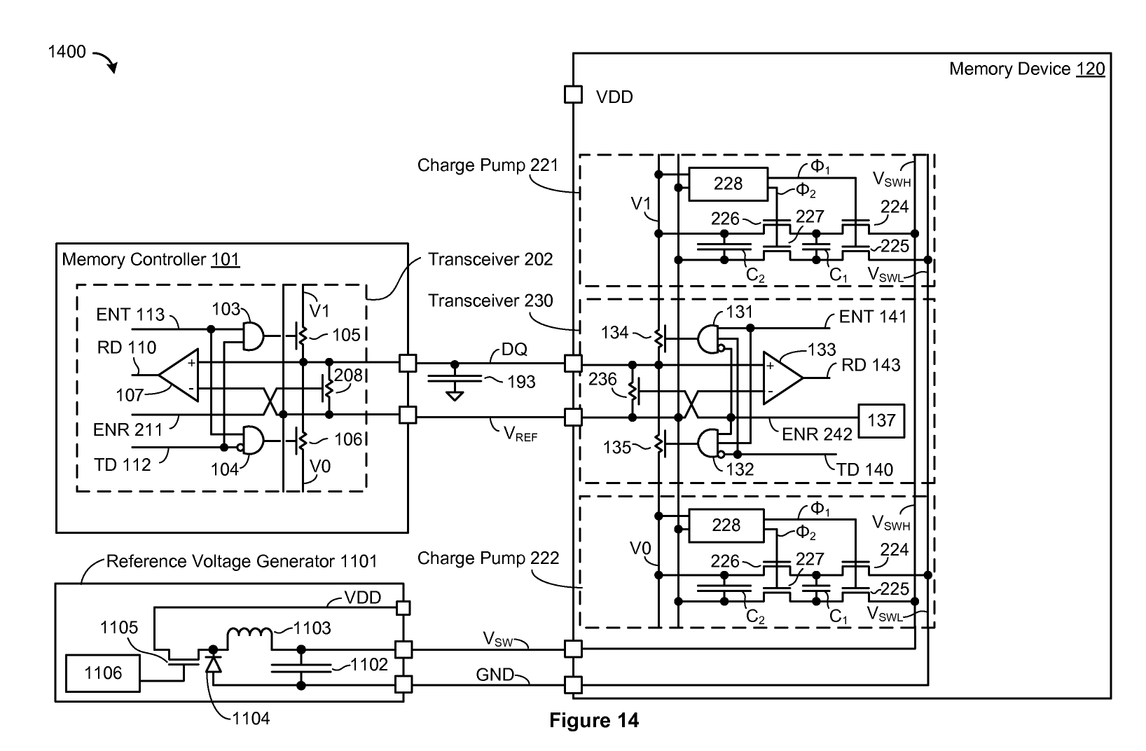

FIG. 14 is a circuit diagram 1400 illustrating an alternative embodiment of the circuit illustrated in FIG. 11, according to some embodiments. Specifically, the parallel termination device 208 in the memory controller 101 is disabled. Furthermore, the control circuit 237 precharges the DQ signal line to a predetermined voltage level (e.g., VREF) between the transmission of symbols, as described with respect to FIG. 9A. The power consumed by the circuit illustrated in FIG. 13 per symbol transmitted is on the order of

$$\frac{C \cdot {( {V}_{1} - {V}_{REF} )}^{2}}{{t}_{BIT}} .$$

Assuming that C is 8 pF, V₁−V₀ is 0.1V, and t_{bit} is 1.25 ns, the power consumed per symbol transmitted is on the order of 0.06 mW.

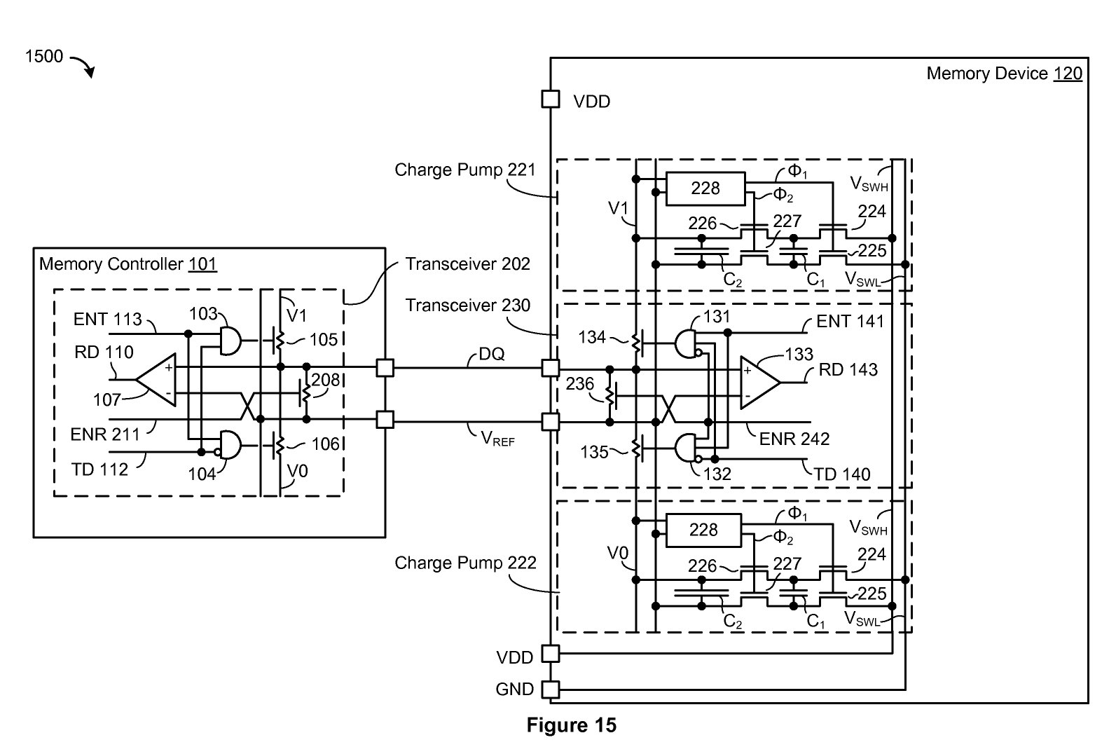

FIG. 15 is a circuit diagram 1500 illustrating the memory controller 101 and the memory device 120, according to some embodiments. In these embodiments, VDD and GND are used as inputs to the charge pumps 221-222. Furthermore, the charge pumps 221-222 are configured so that GND is coupled to the V0 voltage line without charge pumping and VDD is coupled to the V1 voltage line without charge pumping (e.g., the switches 224 and 226 are closed and the switches 225 and 227 are open). These embodiments support legacy operation in systems where the full voltage swing (e.g., 0 to VDD) is required.

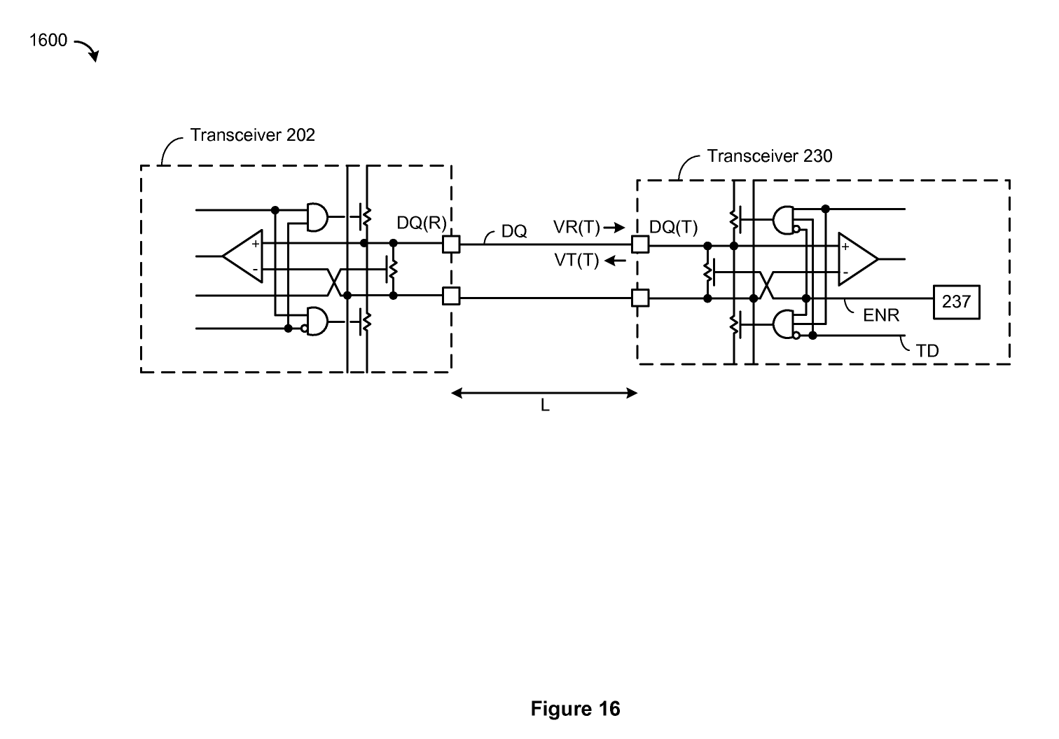

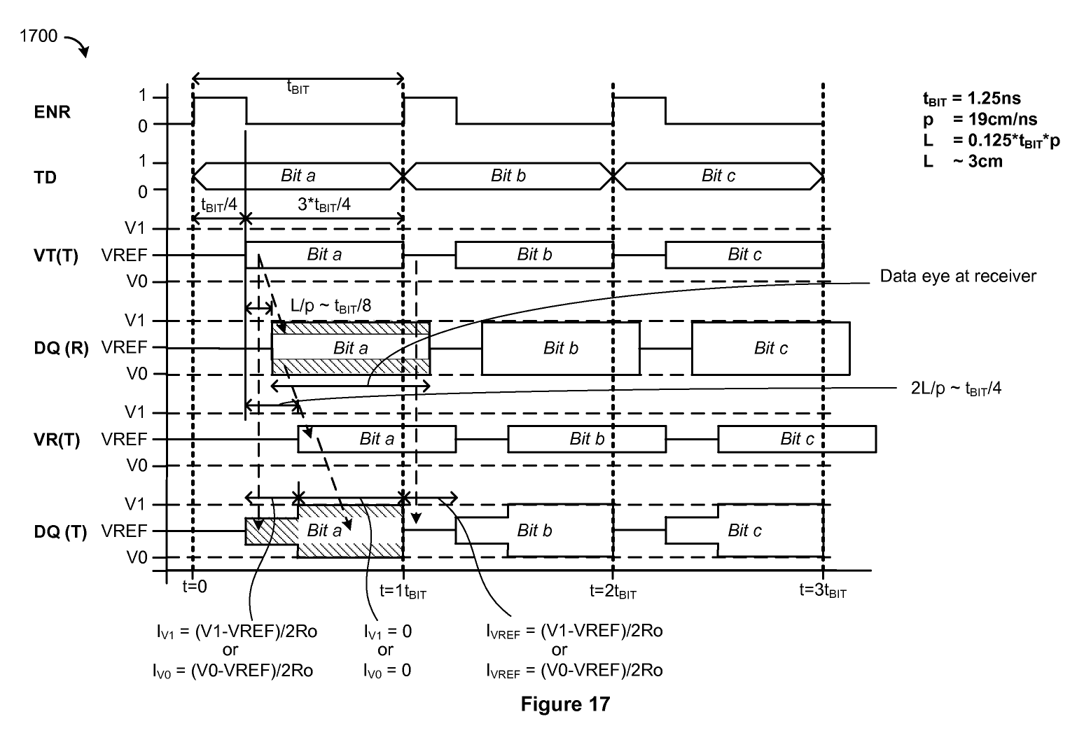

FIG. 16 is a circuit diagram 1600 illustrating the transceiver 202 of the memory controller 101 and the transceiver 230 of the memory device 120 for the circuit illustrated in FIG. 9A, according to some embodiments. FIG. 16 includes a number of variables that are used in the timing diagrams in FIGS. 17-20, which illustrate the effect on the DQ signal when the length of the DQ signal line L is varied. The transceiver 202 includes a DQ(R) port and the transceiver 230 includes a DQ(T) port. The reflected DQ signal is represented by VR(T) and the transmitted DQ signal is represented by VT(T). The transceivers 202 and 230 are coupled to each other through the DQ signal line, which has the length L. In these figures, the transceiver 230 is the transmitter and the transceiver 202 is the receiver.

FIG. 17 is an exemplary timing diagram 1700 illustrating the effect of channel length on the transmitted symbols for the circuit illustrated in FIG. 9A, according to some embodiments. In FIG. 17, the channel length L is 3 cm. The timing diagram 1700 shows the timing of the signals ENR (i.e., the signal that enables or disables the parallel termination device 236), TD (i.e., the transmit data), VT(T) (i.e., the voltage level of the transmitted DQ signal), DQ(R) (i.e., the voltage level at the DQ port of the transceiver 202), VR(T) (i.e., the voltage level of the reflected DQ signal), and DQ(T) (i.e., the voltage level at the DQ port of the transceiver 230). As illustrated in FIG. 17, the signal ENR is asserted at the beginning of the transmission of a respective bit and is asserted for a period of t_{BIT}/4, where t_{BIT} is the period that the respective bit to be transmitted is valid. During the time interval when the signal ENR is asserted, the DQ signal line is precharged to VREF. Thus, the voltage levels VT(T), VR(T), DQ(T), and DQ(R) are at the voltage level VREF during this time interval. After the signal ENR is deasserted, the voltage at VT(T) (and DQ(T)) rises to the midpoint between VREF and V1 (i.e., the high voltage level) due to transmission line effects. Specifically, the voltage rises to a voltage level of ((V1−VREF)/2+VREF). The transmitted signal propagates down the transmission line to DQ(R) after a time interval approximately t_{BIT}/8 (i.e., L/p, where p is the velocity of the signal through the transmission line) after the signal ENR is deasserted. Since the DQ line at the transceiver 202 is not terminated, the signal is reflected back towards the transceiver 230. The reflected signal raises the voltage level of the DQ signal at the transceiver 202 to the full voltage level (e.g., see DQ(R)). The reflected signal VR(T) travels back to the transceiver 230 where the reflected signal VR(T) increases or decreases the voltage level of the DQ signal at the transceiver 230 (i.e., DQ(T)) to the full voltage level (i.e., V1 or V0). The time periods in which respective currents produce these voltage levels are illustrated in FIG. 17. Specifically, the currents flowing from the V1 voltage line (e.g., when a 1 is transmitted) or the current flowing from the V0 voltage line (e.g., when a 0 is transmitted) are I_{V1}=(V1−VREF)/2Rₒ and I_{V0}=(V0−VREF)/2Rₒ, respectively. The currents I_{V1} or I_{V0} are non-zero between the time when the signal ENR is deasserted and when the voltage level at DQ(T) is V1 or V0. After the voltage level at DQ(T) is at V1 or V0, the currents I_{V1} or I_{V0} are zero. During the precharge phase (i.e., when the signal ENR is asserted), the current I_{VREF} (i.e., the current supplied by the reference voltage source VREF) is I_{VREF}=(V1−VREF)/2Rₒ or I_{VREF}=(V0−VREF)/2Rₒ depending on whether a 1 or a 0 was transmitted during the prior transmission interval.

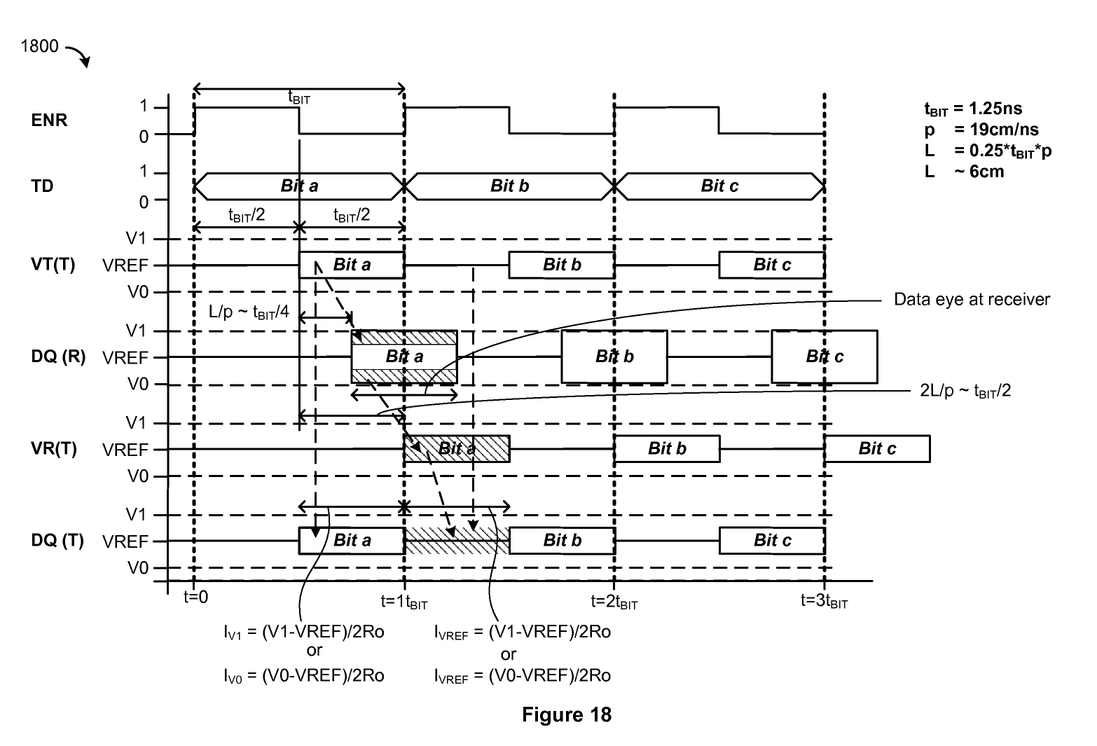

FIG. 18 is another exemplary timing diagram 1800 illustrating the effect of channel length on the transmitted symbols for the circuit illustrated in FIG. 9A, according to some embodiments. The timing diagram in FIG. 18 is similar to the timing diagram in FIG. 17 except that in the timing diagram of FIG. 18, the channel length L is 6 cm. As illustrated in FIG. 18, the signal ENR is asserted at the beginning of the transmission of a respective bit and is asserted for a period of t_{BIT}/2, where t_{BIT} is the period that the respective bit to be transmitted is valid. During the time interval when the signal ENR is asserted, the DQ signal line is precharged to VREF. Thus, the voltage levels VT(T), VR(T), DQ(T), and DQ(R) are at the voltage level VREF during this time interval. After the signal ENR is deasserted, the voltage at VT(T) (and DQ(T)) rises to the midpoint between VREF and V1 (i.e., the high voltage level) due to transmission line effects. Specifically, the voltage rises to a voltage level of ((V1−VREF)/2+VREF). The transmitted signal propagates down the transmission line to DQ(R) after a time interval approximately t_{BIT}/4 (i.e., L/p, where p is the velocity of the signal through the transmission line) after the signal ENR is deasserted. Since the DQ line at the transceiver 202 is not terminated, the signal is reflected back towards the transceiver 230. The reflected signal raises the voltage level of the DQ signal at the transceiver 202 to the full voltage level (e.g., see DQ(R)). The reflected signal VR(T) travels back to the transceiver 230. However, since the reflected signal VR(T) does not reach the transceiver 230 until after the precharge phase on a next data transmission interval begins (i.e., after the signal ENR is enabled), the reflected signal VR(T) does not increases the voltage level of the DQ signal at the transmitter (i.e., DQ(T)) to the full voltage level (i.e., V1 or V0). Instead, the voltage at DQ(T) is precharged to VREF. The time periods in which the respective currents that produce these voltage levels are illustrated in FIG. 18. Specifically, the currents flowing from the V1 voltage line (e.g., when a 1 is transmitted) or the current flowing from the V0 voltage line (e.g., when a 0 is transmitted) are I_{V1}=(V1−VREF)/2Rₒ and I_{V0}=(V0−VREF)/2Rₒ, respectively. The currents Iᵥ₁ or I_{V0} are non-zero between the time when the signal ENR is deasserted until the time when the signal ENR is reasserted. During the precharge phase (i.e., when the signal ENR is asserted), the current I_{VREF} (i.e., the current supplied by the reference voltage source VREF) is I_{VREF}=(V1−VREF)/2Rₒ or I_{VREF}=(V0−VREF)/2Rₒ depending on whether a 1 or a 0 was transmitted during the prior transmission interval.

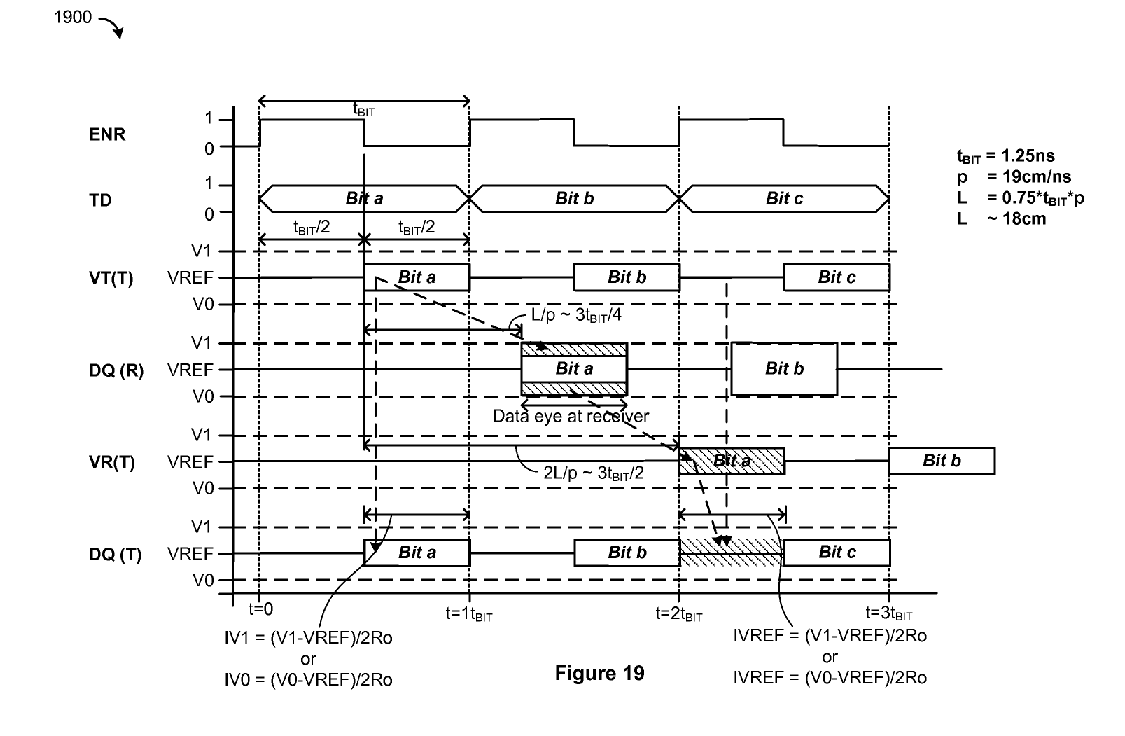

FIG. 19 is another exemplary timing diagram 1900 illustrating the effect of channel length on the transmitted symbols for the circuit illustrated in FIG. 9A, according to some embodiments. The timing diagram in FIG. 19 is similar to the timing diagram in FIG. 17 except that in the timing diagram of FIG. 19, the channel length L is 18 cm. As illustrated in FIG. 19, the signal ENR is asserted at the beginning of the transmission of a respective bit and is asserted for a period of t_{BIT}/2, where t_{BIT} is the period that the respective bit to be transmitted is valid. During the time interval when the signal ENR is asserted, the DQ signal line is precharged to VREF. Thus, the voltage levels VT(T), VR(T), DQ(T), and DQ(R) are at the voltage level VREF during this time interval. After the signal ENR is deasserted, the voltage at VT(T) (and DQ(T)) rises to the midpoint between VREF and V1 (i.e., the high voltage level) due to transmission line effects. Specifically, the voltage rises to a voltage level of ((V1−VREF)/2+VREF). The transmitted signal propagates down the transmission line to DQ(R) after a time interval approximately 3 t_{BIT}/4 (i.e., L/p, where p is the velocity of the signal through the transmission line) after the signal ENR is deasserted. Since the DQ line at the transceiver 202 is not terminated, the signal is reflected back towards the transceiver 230. The reflected signal raises the voltage level of the DQ signal at the transceiver 202 to the full voltage level (e.g., see DQ(R)). The reflected signal VR(T) travels back to the transceiver 230. However, since the reflected signal VR(T) does not reach the transceiver 230 until after the precharge phase of a subsequent transmission interval begins (i.e., after the signal ENR is enabled), the reflected signal VR(T) does not increase the voltage level of the DQ signal at the transmitter (i.e., DQ(T)) to the full voltage level (i.e., V1 or V0). Instead, the voltage at DQ(T) is precharged to VREF. In fact, note that the reflected signal VR(T) does not reach the transceiver 230 until the precharge phase after the transmission of the second bit (i.e., Bit b). The time periods in which the respective currents that produce these voltage levels are illustrated in FIG. 19. Specifically, the currents flowing from the V1 voltage line (e.g., when a 1 is transmitted) or the current flowing from the V0 voltage line (e.g., when a 0 is transmitted) are I_{V1}=(V1−VREF)/2Rₒ and I_{V0}=(V0−VREF)/2Rₒ, respectively. The currents I_{V1} or I_{V0} are non-zero between the time when the signal ENR is deasserted until the time when the signal ENR is reasserted. During the precharge phase (i.e., when the signal ENR is asserted), the current I_{VREF} (i.e., the current supplied by the reference voltage source VREF) is I_{VREF}=(V1−VREF)/2Rₒ or I_{VREF}=(V0−VREF)/2Rₒ depending on whether a 1 or a 0 was transmitted.

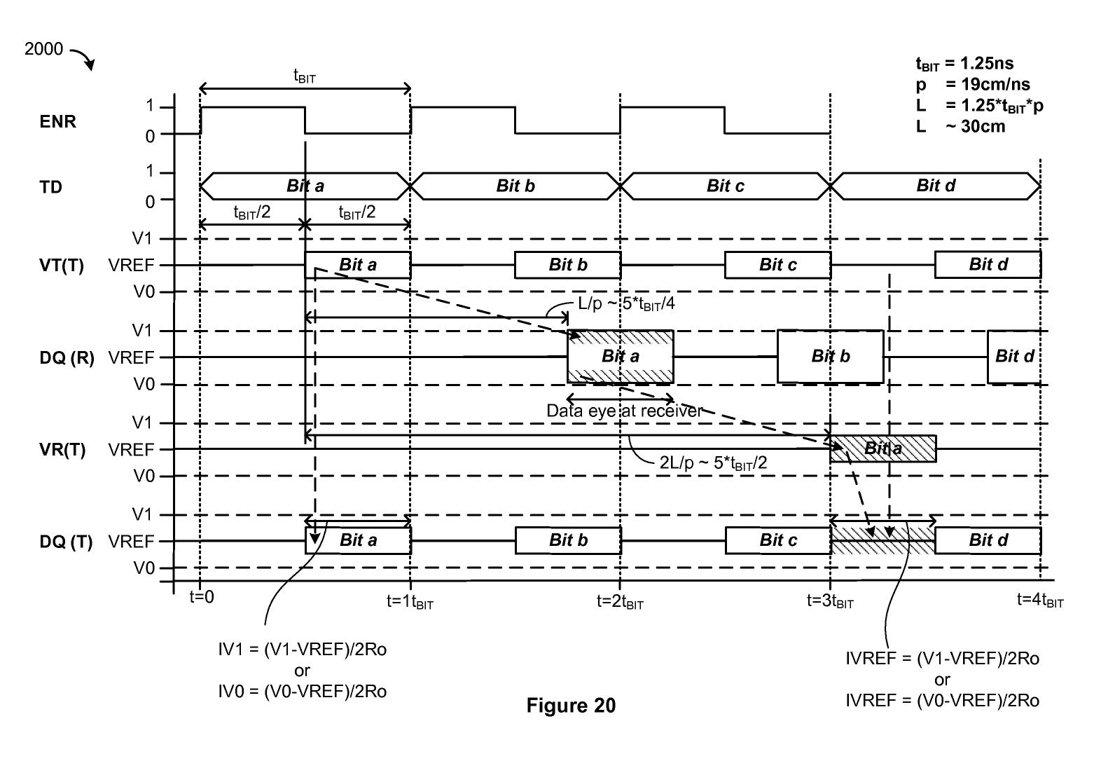

FIG. 20 is another exemplary timing diagram 2000 illustrating the effect of channel length on the transmitted symbols for the circuit illustrated in FIG. 9A, according to some embodiments. The timing diagram in FIG. 20 is similar to the timing diagram in FIG. 17 except that in the timing diagram of FIG. 20, the channel length L is 30 cm. As illustrated in FIG. 20, the signal ENR is asserted at the beginning of the transmission of a respective bit and is asserted for a period of t_{BIT}/2, where t_{BIT} is the period that the respective bit to be transmitted is valid. During the time interval when the signal ENR is asserted, the DQ signal line is precharged to VREF. Thus, the voltage levels VT(T), VR(T), DQ(T), and DQ(R) are at the voltage level VREF during this time interval. After the signal ENR is deasserted, the voltage at VT(T) (and DQ(T)) rises to the midpoint between VREF and V1 (i.e., the high voltage level) due to transmission line effects. Specifically, the voltage rises to a voltage level of ((V1−VREF)/2+VREF). The transmitted signal propagates down the transmission line to DQ(R) after a time interval approximately 5 t_{BIT}/4 (i.e., L/p, where p is the velocity of the signal through the transmission line) after the signal ENR is deasserted. Since the DQ line at the transceiver 202 is not terminated, the signal is reflected back towards the transceiver 230. The reflected signal raises the voltage level of the DQ signal at the transceiver 202 to the full voltage level (e.g., see DQ(R)). The reflected signal VR(T) travels back to the transceiver 230. However, since the reflected signal VR(T) does not reach the transceiver 230 until after the precharge phase of a subsequent transmission interval begins (i.e., after the signal ENR is enabled), the reflected signal VR(T) does not increases the voltage level of the DQ signal at the transmitter (i.e., DQ(T)) to the full voltage level (i.e., V1 or V0). Instead, the voltage at DQ(T) is precharged to VREF. In fact, note that the reflected signal VR(T) does not reach the transceiver 230 until the precharge phase after the transmission of the third bit (i.e., Bit c). The time periods in which the respective currents that produce these voltage levels are illustrated in FIG. 20. Specifically, the currents flowing from the V1 voltage line (e.g., when a 1 is transmitted) or the current flowing from the V0 voltage line (e.g., when a 0 is transmitted) are I_{V1}=(V1−VREF)/2Rₒ and I_{V0}=(V0−VREF)/2Rₒ, respectively. The currents I_{V1} or I_{V0} are non-zero between the time when the signal ENR is deasserted until the time when the signal ENR is reasserted. During the precharge phase (i.e., when the signal ENR is asserted), the current I_{VREF} (i.e., the current supplied by the reference voltage source VREF) is I_{VREF}=(V1−VREF)/2Rₒ or I_{VREF}=(V0−VREF)/2Rₒ depending on whether a 1 or a 0 was transmitted.

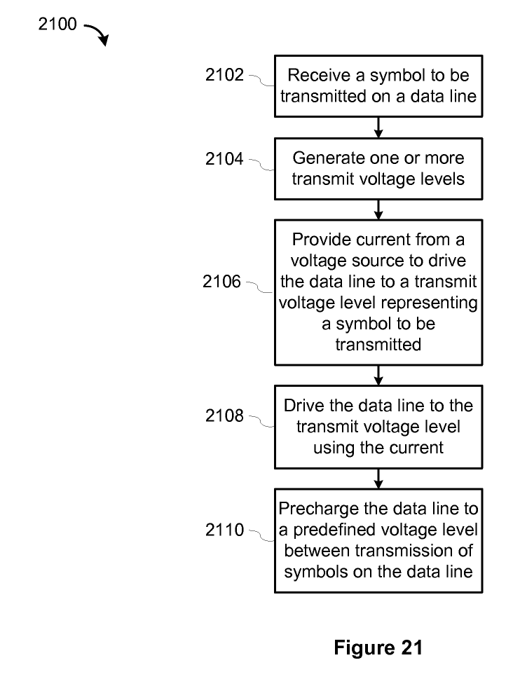

FIG. 21 is a flowchart of a method 2100 for transmitting symbols on a data line, according to some embodiments. An integrated circuit (e.g., the memory device 120, the memory controller 101, etc.) receives (2102) a symbol to be transmitted on a data line. The integrated circuit generates (2104) one or more transmit voltage levels, wherein a respective transmit voltage level represents a respective symbol to be transmitted on the data line. The integrated circuit provides (2106) current from a voltage source to drive the data line to a transmit voltage level representing a symbol to be transmitted, wherein the current drawn from a voltage source is independent of previously transmitted symbols. The integrated circuit then drives (2108) the data line to the transmit voltage level using the current and precharges (2110) the data line to a predefined voltage level between transmission of symbols on the data line.

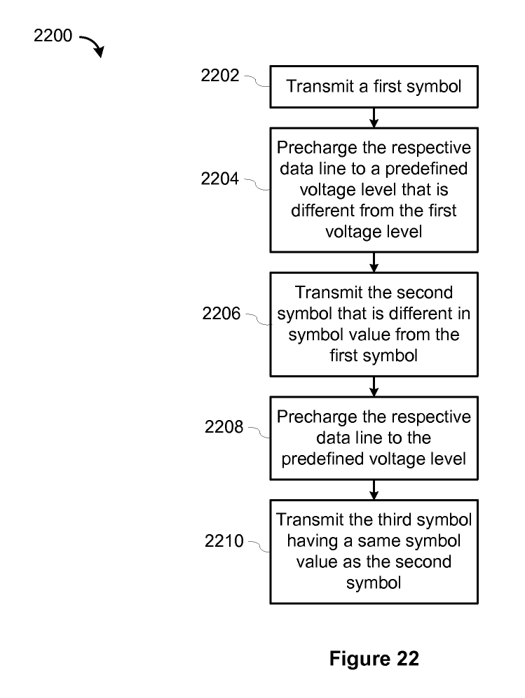

FIG. 22 is a flowchart of a method 2200 for transmitting symbols on a data line, according to some embodiments. An integrated circuit (e.g., the memory device 120, the memory controller 101, etc.) transmits (2202) a first symbol. In some embodiments, the integrated circuit transmits the first symbol by driving a respective data line to a first voltage level by drawing first current from the voltage source, wherein the first voltage level represents the first symbol.

After transmitting the first symbol and before transmitting a second symbol, the integrated circuit precharges (2204) the respective data line to a predefined voltage level that is different from the first voltage level. The integrated circuit then transmits (2206) the second symbol that is different in symbol value from the first symbol. In some embodiments, the integrated circuit transmits the second symbol by driving the respective data line to a second voltage level by drawing second current from the voltage source, wherein the second voltage level represents the second symbol, and wherein the second voltage level is different from the predefined voltage level and also different from the first voltage level. In some embodiments, the second current is substantially the same as the first current.

After transmitting the second symbol and before transmitting a third symbol, the integrated circuit precharges (2208) the respective data line to the predefined voltage level. The integrated circuit then transmits (2210) the third symbol having a same symbol value as the second symbol. In some embodiments, the integrated circuit transmits the third symbol by driving the respective data line to the second voltage level by drawing third current from the voltage source, wherein the second voltage level represents the third symbol, and wherein the second voltage level being different from the predefined voltage level. In some embodiments, the third current is substantially the same as the second current.

In some embodiments, the embodiments described herein are used for external data links. External data links are data links between components (e.g., between two or more memory modules). External data links typically transmit and/or receive signals across long signal lines (e.g., signal lines longer than 2.5 cm). Thus, these signals experience signal integrity issues resulting from crosstalk and parasitic elements (e.g., capacitors, inductors, etc.).

In some embodiments, the embodiments described herein are used for internal data links. Internal data links are data links within a single components (e.g., within a single memory module). Internal data links typically transmit and/or receive signals across shorter distances (e.g., 2 cm or less) than external data links. Thus, these signals do not experience the same signal integrity issues as external data links. Specifically, since inductance is negligible and the signal line is dominated by resistance, the signal lines do not need to be terminated using the characteristic impedance of the signal line. In these embodiments, the parallel termination device at the receiver (e.g., the parallel termination device 208 in FIG. 6) is disabled, the parallel termination device at the transmitter (e.g., the parallel termination device 236 in FIG. 6) is enabled and is low impedance (e.g., having impedance of less than 10 ohms, or alternatively impedance that is 20% or less than the signal line impedance), and the pull-up devices and pull-down devices are low impedance (e.g., the pull-up device 137 and the pull-down device 138 in FIG. 6, or more generally, devices having impedance of less than 10 ohms, or alternatively impedance that is 20% or less than the signal line impedance).

Note that regardless of whether the embodiments described herein are used for internal or external data links, the operation of the data links is the same. Furthermore, the benefits of low-power operation and current flow from the power supply that is independent of the data pattern of the transmitted data are applicable to both internal and external data links.

Note that this specification uses the term “switch” to refer to any type of device that may be opened or closed using a control signal. For example, the switch may be a MOSFET transistor (e.g., a NMOS transistor and/or a PMOS transistor). Also, note that for the sake of clarity, the discussion above describes the transceiver 230 being operated as a transmitter and the transceiver 202 being operated as a receiver. However, the transceiver 230 may be operated as a receiver and the transceiver 202 may be operated as a transmitter. Furthermore, note that any of the circuitry described herein with respect to the memory device 120 may also be included in the memory controller 101.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. An integrated circuit, comprising:
one or more data links, a respective data link including a transmitter circuit configured to transmit a sequence of symbols onto a respective data line, each symbol being represented by one of a plurality of voltage levels, the respective data link including a precharge circuit configured to precharge the data line to a predefined voltage level between transmission of consecutive symbols in the sequence of symbols, the predefined voltage level being different from any of the plurality of voltage levels used to represent the symbols; and
a voltage generator circuit configured to:
generate one or more of the plurality of voltage levels; and
provide current from a voltage source to the transmitter circuit, the transmitter circuit being configured to transmit a respective symbol by driving the respective data line to a respective voltage level using the current provided by the voltage generator circuit, wherein the current drawn from the voltage source during transmission of the respective symbol is independent of the sequence of symbols.

2. The integrated circuit of claim 1, wherein the voltage source supplies a high reference voltage level and a low reference voltage level, and the voltage generator circuit includes:
a first charge-pump voltage supply circuit coupled between the voltage source and the transmitter circuit, and configured to generate a high transmit voltage level that is the sum of the predefined voltage level, and the difference between the high reference voltage level and the low reference voltage level; and
a second charge-pump voltage supply circuit coupled between the voltage source and the transmitter circuit, and configured to generate a low transmit voltage level that is the sum of the predefined voltage level, and the difference between the low reference voltage level and the high reference voltage level.

3. The integrated circuit of claim 2, wherein each of the first and second charge-pump voltage supply circuits includes at least one capacitor, a plurality of switches, and a control circuit configured to selectively close and open the switches to pump charge from the voltage source to the at least one capacitor.

4. The integrated circuit of claim 2, including a switched series capacitor voltage generator circuit configured to generate one or more reference voltages including the high reference voltage level and the low reference voltage level.

5. The integrated circuit of claim 4, wherein the switched series capacitor voltage generator circuit includes:
two or more capacitors coupled in series to the voltage supply;
a transistor coupled to each capacitor, wherein a respective transistor is configured to transfer charge from one terminal of a respective capacitor to another terminal of the respective capacitor in response to a control signal; and
a control circuit coupled to each capacitor, wherein a respective control circuit is configured to:
compare node voltages of the respective capacitor to node voltages of a resistor voltage divider; and
generate the control signal based on the comparison.

6. The integrated circuit of claim 2, including a port for coupling the integrated circuit to the voltage source, wherein the voltage source is external to the integrated circuit.

7. The integrated circuit of claim 6, wherein the external voltage source is an inductive voltage generator that generates one or more reference voltages including the high reference voltage level and the low reference voltage level.

8. The integrated circuit of claim 1, wherein the voltage generator circuit includes:
a first circuit configured to generate a high transmit voltage level that is a voltage level supplied by the voltage source; and
a second circuit configured to generate a low transmit voltage level that is substantially a ground voltage level.

9. The integrated circuit of claim 1, wherein the transmitter circuit has an impedance that substantially matches an impedance of the data line.

10. The integrated circuit of claim 1, wherein the data line is a single ended data line.

11. The integrated circuit of claim 1, including a plurality of the data links, wherein the plurality of data links share a common reference line carrying a reference voltage and each of the data links is configured to be coupled to a single ended data line.

12. The integrated circuit of claim 11, including a switched series capacitor voltage generator circuit configured to generate a plurality of reference voltages including distinct pairs of high and low reference voltage levels for each of the plurality of the data links, wherein each pair of high and low reference voltage levels has a voltage difference that is substantially fixed and substantially the same as the voltage difference as another one of the pairs of high and low reference voltage levels.

13. The integrated circuit of claim 12, wherein the average of the high and low reference voltage levels of respective pairs of data links is offset by a voltage level that is substantially equal to the voltage difference between the high and low reference voltage levels of a respective data link.

14. The integrated circuit of claim 12, wherein a first data link and a second data link in the plurality of data links share the same pair of high and low reference voltage levels in the plurality of reference voltage levels.

15. The integrated circuit of claim 12, wherein a first data link in the plurality of data links uses a first pair of high and low reference voltage levels in the plurality of reference voltage levels and a second data link in the plurality of data links uses a second pair of high and low reference voltage levels in the plurality of reference voltage levels.

16. The integrated circuit of claim 1, including mode control circuitry which, in a first mode, enables the voltage generator circuit, and in a second mode connects a pair of static power supply voltages to the transmitter circuit, wherein the current drawn from the static power supply voltages is dependent on previously transmitted symbols.

17. The integrated circuit of claim 1, wherein the integrated circuit is selected from the group consisting of:
a memory controller; and
a memory device having an array of memory storage cells.

18. The integrated circuit of claim 1, wherein the one or more data links is selected from the group consisting of:
external data links; and
internal data links.

19. A memory module, comprising:
a substrate;
a plurality of the integrated circuits of claim 1 mounted on the substrate.

20. The memory module of claim 19, wherein the each of the plurality of integrated circuits is configured to operate in a first mode, in which current drawn from a voltage source during data transmission is independent on previously transmitted symbols and in a second mode, in which current drawn from a static power supply voltage source during data transmission is dependent on previously transmitted symbols.

21. The memory module of claim 20,
wherein the first mode is a small voltage swing mode; and
wherein the second mode is large voltage swing mode.

22. A method, comprising:
at an integrated circuit:
receiving a symbol to be transmitted on a data line;
generating one or more transmit voltage levels, wherein a respective transmit voltage level represents a respective symbol to be transmitted on the data line;
providing current from a voltage source to drive the data line to a transmit voltage level representing a symbol to be transmitted, wherein the current drawn from a voltage source is independent of previously transmitted symbols;
driving the data line to the transmit voltage level using the current; and
precharging the data line to a predefined voltage level between transmission of symbols on the data line.

23. The method of claim 22, wherein the one or more transmit voltage levels are generated using one or more charge-pump voltage supply circuits using one or more reference voltages.

24. The method of claim 23, wherein the one or more reference voltages are generated using a switched series capacitor voltage generator circuit.

25. The method of claim 23, wherein the one or more reference voltages are generated using an inductive voltage generator.

26. A method performed by an integrated circuit device coupled to a voltage source and a plurality of data lines, comprising:
transmitting a first symbol, including driving a respective data line to a first voltage level by drawing first current from the voltage source, the first voltage level representing the first symbol;
after transmitting the first symbol and before transmitting a second symbol, precharging the respective data line to a predefined voltage level that is different from the first voltage level;
transmitting the second symbol that is different in symbol value from the first symbol, including driving the respective data line to a second voltage level by drawing second current from the voltage source, the second voltage level representing the second symbol, the second voltage level being different from the predefined voltage level, the second current being substantially the same as the first current;
after transmitting the second symbol and before transmitting a third symbol, precharging the respective data line to the predefined voltage level; and
transmitting the third symbol having a same symbol value as the second symbol, including driving the respective data line to the second voltage level by drawing third current from the voltage source, the second voltage level representing the third symbol, the second voltage level being different from the predefined voltage level, the third current being substantially the same as the second current.
